(19) United States
(12) Patent Application Publication
(10) Pub. No.: US 2010/0133529 A1
(43) Pub. Date: Jun. 3, 2010

(54) THIN LIGHT-EMITTING DEVICES AND FABRICATION METHODS

(75) Inventors: Gianni TARASCHI, Somerville, MA (US); Bunmi T. ADEKORE, Arlington, MA (US); Jonathan PIERCE, Piscataway, NJ (US)

Correspondence Address: WILMERHALE/BOSTON, 60 STATE STREET, BOSTON, MA, 02109, US

(73) Assignee: LumenZ LLC, Boston, MA (US)

(21) Appl. No.: 12/563,649

(22) Filed: Sep. 21, 2009

Related U.S. Application Data
(60) Provisional application No. 61/192,548, filed on Sep. 19, 2008.

(51) Int. Cl. H01L 33/00; H01L 29/12; H01L 21/04

(52) U.S. Cl. 257/43; 438/104; 257/94; 257/E33.013; 257/E33.005; 257/E29.068; 257/E21.04

(57) ABSTRACT

A light-emitting device, such as a light-emitting diode (LED), is grown on a substrate including a ZnO-based material. The structure includes a plurality of semiconductor layers and an active layer disposed between the plurality of semiconductor layers. The device is removed from the substrate or the substrate is substantially thinned to improve light emission efficiency of the device.

### CROSS REFERENCE TO RELATED APPLICATIONS

This application claims priority to U.S. Provisional Application No. 61/192548, filed on Sep. 19, 2008, which is incorporated herein by reference in its entirety.

### FIELD OF INVENTION

The invention relates generally to semiconductor light-emitting devices and more specifically to semiconductor light-emitting devices including zinc oxide materials.

### BACKGROUND

Semiconductor light-emitting devices, such as light-emitting diodes (LEDs) and laser diodes (LDs), can serve as light sources that have the potential to be efficient, robust, and environmentally friendly. Light-emitting devices emitting short wavelengths such as blue and green light have been created using Group III-nitride materials systems, such as the A1InGaN materials system. At the longer wavelength end of the spectrum, light-emitting devices emitting red, orange, and yellow light have been fabricated using Group III-phosphide materials systems, such as the AIInGaP materials system.

Although these material systems have enabled LEDs and LDs that emit light across the visible spectrum, the unacceptably high cost and low material quality of Group III-nitride light-emitting devices impedes the further proliferation of semiconductor light-emitting devices in many illumination applications, such as general lighting.

### SUMMARY OF THE INVENTION

In one aspect, a semiconducting device comprises a plurality of semiconductor layers, where at least one layer is of a first conductivity type, for example, p-type. A second layer is of a different conductivity type than the first layer is provided, for example, n-type. A third layer is disposed between the first and second layers. According to one embodiment, at least one of the first, second and third layer is a ZnO-based semiconductor where the dislocation density of the third layer is less than 10⁶ cm⁻². Further, each of the first, second and third layers is free from the growth substrate upon which each layer was deposited or grown.

In one aspect, a semiconducting device comprises a plurality of semiconducting layers, where a first layer is a ZnO-based semiconductor of a first conductivity type, for example, p-type. A second ZnO-based layer of a different conductivity type that the first layer is provided, for example, n-type. A third ZnO-based semiconductor layer is disposed between the first and second ZnO-based semiconductor layers and has a dislocation density of about 10⁶ cm⁻², where each of the first, second and third ZnO-based semiconductor layers is free from a growth substrate upon which each layer was deposited or grown.

In one aspect, a light-emitting device with peak emission wavelength less than about 500 nm comprises a plurality of semiconductor layers, where at least one layer is of a first conductivity type, for example, p-type. A second layer is of a different conductivity type than the first layer is provided, for example, n-type. A third layer is disposed between the first and second layers. According to one embodiment, at least one of the first, second and third layer is a ZnO-based semiconductor where the dislocation density of the third layer is less than 10⁶ cm⁻². Further, each of the first, second and third layers is free from the growth substrate upon which each layer was deposited or grown.

In one aspect, a method for fabricating a semiconducting device is provided, in which a first ZnO-based layer of material is deposited on a ZnO-based substrate. The method further provides for the depositing of a second ZnO-based layer of material. The method further provides for the depositing of a third ZnO-based layer of material. Further, the method provides for removing at least a portion of the ZnO-based substrate. According to various embodiments, the method further provides for the deposition of a fourth ZnO-based layer of material. In some embodiments, the fourth ZnO-based material is an etch stop layer, where the ZnO-based substrate is at least partially removed by an etchant that is selective or partially selective for the ZnO-based substrate over the ZnO-based etch stop layer. According to other embodiments, the fourth ZnO-based layer is a release layer, where the ZnO-based substrate is removed by an etchant that is selective or at least partially selective for the ZnO-based release layer over the ZnO-based substrate.

In one aspect, a semiconducting device comprises a plurality of semiconductor layers, where at least one layer is of a first conductivity type, for example, p-type. A second layer is of a different conductivity type than the first layer is provided, for example, n-type. A third layer is disposed between the first and second layers. According to one embodiment, at least one of the first, second and third layer is a ZnO-based semiconductor where the dislocation density of the third layer is less than 10⁶ cm⁻². Each of the first, second and third layers is grown on a thinned substrate. According to various embodiments, the substrate is thinned to a thickness between about 0 and 50 μm.

### BRIEF DESCRIPTION OF DRAWINGS

FIG. 1 is a cross-sectional view of a light-emitting device including a thin portion;

FIGS. 2A-2J illustrate intermediate structures that may be formed during the fabrication of device structures provided herein;

FIG. 3 illustrates a cross-sectional view of a light-emitting device including a textured reflective surface;

FIG. 4 illustrates a cross-sectional view of a light-emitting device including a plurality of textured layers;

FIG. 5 illustrates a cross-sectional view of a light-emitting device;

FIG. 6 illustrates a cross-sectional view of a light-emitting device having a lateral electrical contacting geometry and mounted in a flip-chip configuration;

FIG. 7 illustrates a cross-sectional view of a light-emitting device having a lateral electrical contacting geometry and mounted in a flip-chip configuration;

FIG. 8 illustrates a cross-sectional view of a light-emitting device having a lateral electrical contacting geometry and mounted in a flip-chip configuration;

FIG. 9 illustrates a cross-sectional view of a light-emitting device wherein texturing of a primary light emission surface may be achieved via patterning and etching; and

FIG. 10 illustrates a cross-sectional view of a light-emitting device according to an alternative embodiment wherein texturing of a primary light emission surface may be achieved via patterning and etching.

### DETAILED DESCRIPTION

Reference now will be made in detail to the presently preferred embodiments of the invention. Such embodiments are provided by way of explanation of the invention, which is not intended to be limited thereto. In fact, those of ordinary skill in the art may appreciate upon reading the present specification and viewing the present drawings that various modifications and variations can be made.

Before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting. Numerous embodiments are described in this patent application, and are presented for illustrative purposes only. The described embodiments are not intended to be limiting in any sense. The invention is widely applicable to numerous embodiments, as is readily apparent from the disclosure herein. Those skilled in the art will recognize that the present invention may be practiced with various modifications and alterations. Although particular features of the present invention may be described with reference to one or more particular embodiments or figures, it should be understood that such features are not limited to usage in the one or more particular embodiments or figures with reference to which they are described.

As such, those skilled in the art will appreciate that the conception, upon which this disclosure is based, may readily be utilized as a basis for the designing of other structures, methods and systems for carrying out the several purposes of the present invention. It is important, therefore, that the invention be regarded as including equivalent constructions to those described herein insofar as they do not depart from the spirit and scope of the present invention.

For example, the specific sequence of the described process may be altered so that certain processes are conducted in parallel or independent, with other processes, to the extent that the processes are not dependent upon each other. Thus, the specific order of steps described herein is not to be considered implying a specific sequence of steps to perform the process. Other alterations or modifications of the above processes are also contemplated. For example, further insubstantial approximations of the process and/or algorithms are also considered within the scope of the processes described herein.

In addition, features illustrated or described as part of one embodiment can be used on other embodiments to yield a still further embodiment. Additionally, certain features may be interchanged with similar devices or features not mentioned yet which perform the same or similar functions. It is therefore intended that such modifications and variations are included within the totality of the present invention.

Solid-state light-emitting device structures are typically fabricated using epitaxial growth of semiconductor device layers onto an epitaxial growth substrate. However, in some instances, the epitaxial growth substrate may impede device performance and/or reliability. Examples of possible optical effects of the growth substrate on the device performance may include light absorption by the substrate and/or light waveguiding in the substrate. In addition, possible electrical effects may include increased electrical series resistivity due to the substrate that may increase the device forward voltage. Furthermore, the thermal resistivity of the substrate may contribute to an elevated device operating temperature and hence reduced internal quantum efficiency.

In some embodiments presented herein, light-emitting devices, such as LEDs and/or LDs, may have a thin semiconductor portion, whereby such devices may have a portion or all of their epitaxial growth substrate removed so as to create the thin semiconductor portion. As described, it may be beneficial to remove a substrate that may absorb light emitted by the active region. For example, if the active layer emits light having a wavelength smaller than the bandgap of the substrate. Similarly, substrate removal may also be useful if the substrate exhibits free carrier absorption for wavelengths larger than the bandgap of the substrate. Removal of the substrate can also allow heat to be removed from the device more efficiently.

In some devices described herein, ZnO-based materials may be employed to form part or the entire semiconductor portion of a light-emitting device, for example the LED semiconductor layers. Furthermore, in some instances a ZnO-based substrate (e.g., ZnO, ZnMgO, etc.) may be used to provide an epitaxial growth substrate on which LED layers may be deposited. As will be generally understood, the crystal lattice of the epitaxial growth substrate affects the crystal lattice of material layers that are subsequently deposited. Due to potentially low lattice mismatch between the substrate and epitaxial layers, such a substrate may enable the growth of low defect density monocrystalline (i.e., single crystal) epitaxial layers (e.g., ZnO-based epitaxial layers) that may enable efficient device performance.

Generally, ZnO-based semiconductors and LEDs have been grown on sapphire substrates as sapphire is significantly cheaper (e.g., 1/10 the price) than ZnO-based epitaxial growth substrates and is available in larger wafer diameters. However, growth of ZnO-based epitaxial layers on materials such as, for example, sapphire can lead to lattice mismatches between the ZnO-based layers and the underlying substrate. These lattice mismatches can introduce a significant density of defects, such as dislocations (e.g., threading dislocations, partial vertical dislocations) and/or stacking faults, in subsequently deposited layers and lead to deleterious effects in the internal quantum efficiency of the ZnO-based LED - dislocations densities beyond a certain threshold may affect performance of the resultant device. For example, dislocation densities beyond about 10⁶ cm⁻² to about 10⁸ cm⁻² in the active layer of the ZnO-based LED can cause non-radiative recombination of carriers in the active layer. This directly affects the internal quantum efficiency of any resultant device as the number of recombinations producing photons decreases. Consequently, it is an object of the present invention to reduce the dislocation density in ZnO-based LED device and non-device structures to avoid non-radiative recombination events in the active layer and increase the internal quantum efficiencies of the resultant semi-conducting devices.

In embodiments where the epitaxial substrate is a ZnO substrate, substrate removal may be beneficial if the active layer emits light having a photon energy larger than or equal to the ZnO bandgap energy, which is in the near UV portion of the electromagnetic spectrum at about 370 nm. Similarly, substrate removal may also be useful if the substrate exhibits free carrier absorption for photon energies smaller than the bandgap of the ZnO substrate, such as free carrier absorption of visible light emitted by the active layer. Hence, substrate removal (e.g., partial or complete substrate removal) may be utilized and may be potentially beneficial for both UV and visible light-emitting devices by increasing light extraction from the device. However, as will be understood, substrate removal can result in damage to device layers of the resultant ZnO-based LED, causing, for example, point defects (e.g., vacancies, interstitials, and/or anti-sites) in one or more layers that can migrate to the active layer (or other device layers). It should be appreciated that semiconductor devices formed of other materials such as GaInAIN materials or AIInGaP materials do not have problems with point defects, since such defects do not form in significant numbers to affect device operation. In contrast, in the case of ZnO, for example, etchants used for removing substrates can etch or partially etch device layers creating point defects at their surfaces that can migrate within the crystal lattice structures of the device during operation. In particular, ZnO-based p-type layers (as well as the active layer) are particularly sensitive and must be protected from damage to crystal structures or introduction of impurities. As mentioned above, defects within the active layer of ZnO-based LED devices can result in non-radiative recombination events of carriers, reducing the internal quantum efficiency of the device. As such, it is an object of the invention to remove ZnO-based LED device structures from the ZnO-based substrate upon which they are grown without introducing point defects (e.g., beyond a concentration of about 10¹⁸ cm⁻³) that may migrate to the active layer (or layers) and affect device performance.

As described in greater detail in other portions of the present disclosure herein, one or more etch stop layers or buffer layers may be provided between the ZnO substrate and ZnO-based LED device layers to allow removal of the ZnO-substrate without damaging the device layers by the etchant or etchants, or by other removal processes (e.g., mechanical removal such as polishing or grinding, laser liftoff, ion-assisted delamination). For example, according to some embodiments, an etch-stop layer or layers may be deposited on a ZnO substrate or ZnO-based substrate. In embodiments where etch stop layers are deposited, the etch stop layer or layers may be ZnO-based to aid in crystal lattice matching of subsequently deposited layers and prevent crystal lattice dislocation formation.

According to various embodiments, ZnO-based device layers are deposited on the etch stop layer or layers and are protected from damage during removal of the substrate by the presence of the etch stop layer between the device layers and the etchant. The ZnO-based device layers may be a homo-structure (i.e., the n-type and p-type cladding layers surrounding the ZnO-based active layer may have the same chemical composition or bandgap) or may be hetero-structures (i.e., the n-type and p-type clading layers surrounding the ZnO-based active layer may have different chemical composition or bandgaps). As will be understood, each layer described above may be comprised of one or more layers without departing from the spirit of the present invention. Additionally, further layers may be deposited, for example, one or more contact layers, and one or more waveguiding layers without departing from the spirit of the present invention. In embodiments providing additional waveguiding and/or electrical contact layers, each layer may be ZnO-based to aid in maintaining a crystal lattice that reduces dislocation formation.

Subsequent to the deposition or epitaxial growth of device layers over the etch stop layer or layers, according to various embodiments of the present invention the top-most layer (i.e., the last layer deposited) is attached to a sub-mount. As will be understood, layers in contact or near the ZnO-based p-type layer may introduce impurities into the layer through diffusion that may act as compensation for the p-dopants. As such, to protect the highly sensitive ZnO-based p-type layer from damage, in some embodiments the n-type layer is attached to a sub-mount. Alternatively, the ZnO-based p-type layer may be attached to the sub-mount. According to some embodiments, attachment of the top-most layer to the sub-mount may involve the application of heat and/or pressure to achieve a sufficiently strong bond to the sub-mount. In some embodiments of the present invention, after attachment to the sub-mount the deposition substrate is removed by one or more etchants that selectively etch the substrate and stop on the etch stop layer or layers. According to some embodiments, the device layers act as an etch-stop, wherein the etchant or enchants selectively remove the ZnO or ZnO-based substrate and stop on the device layers without causing damage. In embodiments in which device layers act as an etch stop additional etch stop layers may be optionally provided.

Optionally, according to various embodiments, the one or more etch stop layers may be removed. In some embodiments, the etch stop layers are electrically conductive and/or transparent and do not affect the operation of the resulting ZnO-based LED. In embodiments in which the etch stop layer or layers are retained the etch stop layer can allow electrical contact to be formed to at least one cladding layer. In other embodiments, the resultant structures are etched to allow electrical contacts to be formed.

According to other embodiments of the present invention, the etch stop layer may be replaced with a release layer between the substrate and device layers. The release layer may be susceptible to etching by one or more etchants that do not etch or significantly etch the substrate or device layers. The release layer includes one or more ZnO-based materials to allow lattice matching with subsequently deposited layers and maintain low dislocation densities. In embodiments providing a release layer, the substrate may be removed or lifted off by laterally etching the release layer with an etchant selective for the release layer material. As will be understood, the composition of the release layer may be changed to allow selection of an etchant or change the etch rate.

Although some embodiments presented herein may be described in the context of ZnO-based epitaxial layers and/or substrates, it should be appreciated that at least some aspects of structures, devices, and methods described herein may apply to other materials systems, and are not limited to ZnO-based materials.

ZnO-based materials include an oxide containing Zn, examples of which include oxides of Group IIA elements and/or Group IIB elements with Zn, in addition to ZnO itself. Specific examples of ZnO-based materials include ZnO, ZnMgO, ZnCaO, ZnBeO, ZnSrO, ZnBaO, ZnCdO, and alloys of these materials, such as MgCdZnO. Each of the above materials may be optionally alloyed with one or more Group VI elements, such as Group VIA elements (e.g., Te, Se, and/or S).

In some embodiments, a ZnO-based material includes alloying elements such as Group II elements (e.g., Mg, Be, Ca, Sr, Ba, Cd, or other related elements), Group VI elements (e.g., Te, Se, S, or other related elements) or combinations thereof. The alloying elements can enable the formation of a ternary or quaternary compound that may allow for greater flexibility in engineering the bandgap and/or lattice parameter(s) of the ZnO-based material, which may be useful in device structures that employ stacked semiconductor epitaxial layers having differing bandgaps (e.g., LEDs, LDs).

In some embodiments, alloying with an element on the oxygen sub-lattice can vary (e.g., decrease and/or increase) the bandgap of a ZnO-based material. Such alloying is described in PCT publication WO/2008/073469, filed Dec. 11, 2007 entitled “Zinc Oxide Multi-Junction Photovoltaic Cells and Optoelectronic Devices,” commonly owned by the assignee and herein incorporated by reference in its entirety. Alloying with an element on the oxygen sub-lattice can further vary (e.g., decrease or increase) the bandgap of the ZnO-based material beyond what may be achieved using only alloying with an element on the zinc sub-lattice (e.g., as a result of the solubility limit of the zinc sub-lattice element in ZnO). Oxygen sub-lattice alloying elements that can result in a variation of the bandgap of a ZnO-based material can include Te, Se, and/or S. In some embodiments, bandgaps of less than about 3 eV may be achieved. In some embodiments, the bandgap of the alloy may be greater than about 2 eV and less than about 3 eV. In some embodiments, bandgaps of less than about 2 eV may be achieved. In some embodiments, the bandgap of the alloy may be greater than about 1 eV and less than about 2 eV.

A ZnO-based material may be a p-type conductivity semiconductor, an n-type conductivity semiconductor, or an intrinsic conductivity semiconductor. P-type dopants may be included in the ZnO-based material, including one or more suitable Group IA, IB, VA and/or VB elements, such as K, Au, Ag, N, P As, Sb and/or other appropriate elements. N-type dopants may be included in the ZnO-based material, including one or more suitable Group III elements (e.g., B, Al, Ga, In, and/or T1) and/or Group VII elements (e.g., F, Cl, Br, I).

Co-doped compensated semiconductors (e.g., a ZnO-based semiconductor, a Group-III nitride semiconductor) includes both n-type and p-type dopants. N-type co-doped compensated semiconductors may have a concentration of activated donors greater than a concentration of activated acceptors. P-type co-doped compensated semiconductors may have a concentration of activated acceptors greater than a concentration of activated donors. Intrinsic co-doped compensated semiconductors may have a concentration of activated acceptors about equal to a concentration of activated donors.

N-type, p-type, and intrinsic semiconductor layers may enable the formation of various semiconductor device structures, as described further below. In some of the device structures, semiconductor layers (e.g., active layer, one or more cladding layers, and/or one or more contact layers) or portions of the semiconductor layers may have an n-type conductivity, p-type conductivity, or intrinsic conductivity, whereby the intrinsic conductivity may be achieved via co-doping or via no intentional doping.

Although many embodiments described are related to light-emitting devices, such as LEDs and laser diodes, it should be appreciated that thin device structures and processes to produce such structures may be utilized for other devices such as other optoelectronic, photonic, or electronic devices (e.g., photodiodes, photovoltaics, excitonic devices, excitonic integrated circuits, excitonic light switches, transistors).

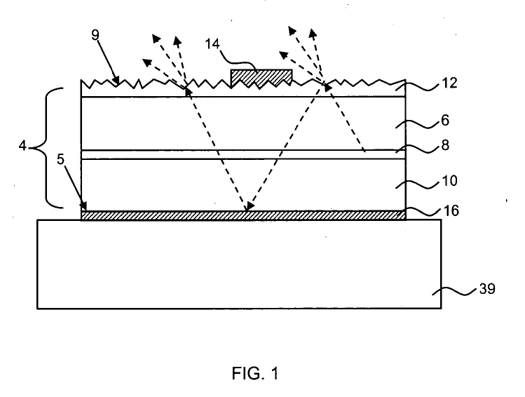

FIG. 1 is a cross-sectional view of a light-emitting device including a thin portion that may be mounted onto a sub-mount. The device structure may be formed by the partial or complete removal of the epitaxial growth substrate, as described further in detail herein.

The light-emitting device includes a primary light emission surface 9 and a reflective surface 5 configured to reflect light generated by the device. A thin portion 4 of the light-emitting device between a light emission 9 and a reflective surface 5 may have a thickness of less than about 50 microns (e.g., less than about 20 microns, less than about 10 microns, less than about 5 microns, less than about 2 microns). Thin portion 4 includes a semiconductor portion and potentially additional material portions, such as one or more transparent conducting layers and/or one or more electrically insulating layers.

In some embodiments, thin portion 4 includes a textured layer having a textured surface configured to serve as the primary light emission surface 9. In some embodiments, the textured surface has a RMS roughness of between about 0.05 μm and about 5 μm, and preferably between about 0.1 μm and about 3 μm. Texturing of primary light emission surface 9 may serve as light extraction features. The textured layer (e.g., a ZnO-based layer) may be disposed over the active layer 8. The textured layer includes part or all of a transparent conducting layer, n-type semiconductor layer(s), p-type semiconductor layer(s), and/or an electrically insulating layer. In some embodiments, the textured layer may be a monocrystalline layer. Alternatively, the textured layer may be polycrystalline, nanocrystalline, or amorphous. The textured layer may be formed of one or more materials (e.g., ZnO-based materials) having a bandgap larger than the bandgap of the active layer, larger than the bandgap of quantum wells in the active layer, and/or larger than semiconductor layers, thereby minimizing the absorption of generated light by the textured layer. The textured layer may have a refractive index of less than 2.3 at the light emission wavelength of the active layer 8. The textured layer may have a refractive index of greater than 1.9 at the light emission wavelength of the active layer 8. The textured layer may have a refractive index that is substantially the same (i.e., having a refractive index difference of less than about±0.3) as the refractive index of the n-type semiconductor layer or the p-type semiconductor layer on which it may be disposed. In some embodiments, the light emission wavelength of the active layer 8, which may be a peak emission wavelength, is greater than about 360 nm (e.g., greater that about 400 nm, greater than about 450 nm). In some embodiments, the light emission wavelength of the active layer 8, which may be a peak emission wavelength, is less than about 600 nm (e.g., less that about 500 nm, less than about 450 nm).

The textured layer includes a transparent material. Examples of transparent materials include ZnO-based materials, MgO, ZnS, CdS, In₂O₃, TiO₂, PbO, NiO, ZnSnO, indium tin oxide (ITO), or any combination thereof. The textured layer includes a transparent oxide. Examples of transparent oxides includes ZnO-based materials, MgO, In₂O₃, TiO₂, PbO, NiO, ZnSnO, indium tin oxide (ITO), or any combination thereof. The textured layer includes a transparent conductive material, such as a transparent conductive oxide. Examples of transparent conductive oxides include ZnO-based materials, In₂O₃, indium tin oxide (ITO), or any combination thereof. The textured layer includes n-type and/or p-type semiconductor materials (e.g., an n-type and/or p-type ZnO-based semiconductor). In some embodiments, the textured layer may be part or all of an epitaxial growth substrate (e.g., having backside texturing) on which the n-type semiconductor layer, the p-type semiconductor layer, and the active layer 8 are disposed. The textured layer may be a monocrystalline layer having a low dislocation density of less than about 10⁶ cm⁻² (e.g., less than about 10⁵ cm⁻², less than about 10⁴ cm⁻², less than about 10³ cm⁻², less than about 10² cm⁻²). Such a low dislocation density may be a result of low lattice mismatch between the textured layer and the layer on which it is deposited.

In some embodiments, thin portion 4 includes a transparent conducting layer 12 that may serve as a current spreading layer. In some embodiments, transparent conducting layer 12 may serve as the textured layer having the primary light emission surface 9. However, it should be appreciated that other configurations are possible, and that the primary light emission surface may be the surface of any other layer(s). For example, in devices where transparent conducting layer 12 is absent, the surface of semiconductor layer 6 may be textured to provide a primary light emission surface. Alternatively or additionally, a textured electrically insulating layer may disposed on semiconductor layer 6 and/or transparent conducting layer 12 so as to provide a primary light emission surface.

The semiconductor portion of the light-emitting device includes a plurality of semiconductor layers and an active layer 8 disposed between the plurality of semiconductor layers. The plurality of semiconductor layers may comprise a first conductivity-type semiconductor layer 6 (e.g., n-type or p-type) and a second conductivity-type semiconductor layer 10 (e.g., p-type or n-type), and the active layer 8 may be disposed between semiconductor layer 6 and semiconductor layer 10. First conductivity-type semiconductor layer 6 may include a plurality of layers with different compositions and/or doping levels, such as one or more cladding layers, one or more contact layers, and/or one or more waveguiding layers (e.g., for laser diode structures). Second conductivity-type semiconductor layer 10 may include a plurality of layers with different compositions and/or doping levels, such as one or more cladding layers, one or more contact layers, and/or one or more waveguiding layers (e.g., for laser diode structures).

The light-emitting device may include an electrode 16 that may be disposed under second conductivity-type semiconductor layer 10. Electrode 16 may comprise one or more layers, which may include one or more metal layers. In some embodiments, electrode 16 may provide an Ohmic electrical contact to the adjacent semiconductor (e.g., second conductivity-type semiconductor layer 10). Electrode 16 includes one or more reflective metal layers, such as a layer of Ag and/or Al, that may thereby form the reflective surface 5. In some embodiments, reflective surface 5 may be in direct contact with the second conductivity-type semiconductor layer 10. Alternatively, an optically transparent material, that may optionally also be electrically conductive, may be disposed between a portion or all of second conductivity-type semiconductor layer 10 and reflective surface 5.

Electrode 16 includes one or more electrical contacting metal layer(s) that may be disposed on the reflective metal layer. Electrode 16 may serve as an Ohmic electrical contact to the adjacent semiconductor (e.g., an adjacent oxide-based semiconductor). Examples of electrode metals or metal stacks include Ti/Au, Ti/Al, Ti/Al/Au, Ti/Al/Pt/Au, Cr/Au, Cr/Al, Cr/Al/Au, Al/Au, Al, Al/Pt, In, Ru or the like to form an n-type contact, and Ni/Al/Au, Ni/Ti/Au, Ag or the like to form a p-type contact. Part or all of electrode 14 may serve as an electrical contact pad (e.g., bond pad), to which a wire bond or a package metal trace may be attached (e.g., via solder or bump bonding) to provide an external electrical connection.

Alternatively or additionally, a distributed Bragg reflector (DBR), may be formed under second conductivity-type semiconductor layer 10. The DBR may be formed directly on the surface of semiconductor layer 10. The DBR may be formed of a plurality of semiconductor, insulator, and/or conductive layers having difference refractive indices. The DBR may have the same conductivity type as semiconductor layer 10. The DBR may be formed of a plurality of ZnO-based layers having different refractive indices, such as alternating layers of ZnO and/or ZnO-based alloys. Examples of ZnO-based alloys used to form the DBR include alloying elements such as Group II elements (e.g., Mg, Be, Ca, Sr, Ba, Cd, or other related elements), Group VI elements (e.g., Te, Se, S, or other related elements), other suitable elements, or combinations thereof. The DBR may be formed of monocrystalline layers that may be deposited during the growth process that may be used to form the active layer and cladding and contact semiconductor layers.

In some embodiments, the surface of second conductivity-type semiconductor layer 10 on which electrode 16 may be formed may be textured, thereby providing for the formation of a textured reflective layer, such as a textured metal layer. A textured reflective layer may frustrate total internal reflection in the semiconductor structure and facilitate light extraction.

The light-emitting device includes an electrode 14 that may be disposed on (e.g., either directly or indirectly) first conductivity-type semiconductor layer 6. Electrode 14 may be formed of any suitable metal that may provide electrical contact with the adjacent semiconductor (e.g., an adjacent oxide-based semiconductor), such as transparent conductive layer 12 or first conductivity-type semiconductor layer 6 in configurations where the transparent conductive layer 12 may be absent. Electrode 14 may serve as an Ohmic electrical contact to the adjacent semiconductor (e.g., an adjacent oxide-based semiconductor). Examples of electrode metals or metal stacks include Ti/Au, Ti/Al, Ti/Al/Au, Ti/Al/Pt/Au, Cr/Au, Cr/Al, Cr/Al/Au, Al/Au, Al, Al/Pt, In, Ru or the like to form an n-type contact, and Ni/Al/Au, Ni/Ti/Au or the like to form a p-type contact. Part or all of electrode 14 may serve as an electrical contact pad (e.g., bond pad), to which a wire bond or a package metal trace may be attached (e.g., via solder or bump bonding) to provide an external electrical connection.

Sub-mount 39 may be any structure that supports the aforementioned device layers. Sub-mount 39 may extend at least the entire area of the supported device layers. In some embodiments, sub-mount 39 may extend beyond the entire area of the supported device layers. Sub-mount 39 may be electrically conductive. Alternatively, sub-mount 39 includes an electrically insulating core and electrically conducting surface layers, for example electrically conductive trace layers (e.g., metal traces). Sub-mount 39 includes a metal core, for example a core including aluminum, copper, tungsten, other suitable metals, or combinations thereof. Sub-mount 39 includes a ceramic core, and optionally one or more metal traces on the surface of the ceramic core. Sub-mount 39 includes a semiconductor core (e.g., silicon substrate) that includes other devices that can provide enhanced functionality to the light-emitting device. For example, the sub-mount 39 includes electrostatic protection circuitry for the light-emitting device.

The plurality of semiconductor layers (e.g., layers 6 and 10) and/or the active layer 8 may have a hexagonal crystal structure (e.g., a wurtzite crystal structure), examples of which include ZnO-based semiconductors or Group III-nitride semiconductors. The plurality of semiconductor layers (e.g., layers 6 and 10) and the active layer 8 may be epitaxially deposited on an epitaxial growth substrate that may also have a hexagonal crystal structure (e.g., a wurtzite crystal structure). After epitaxial deposition of the device layers (e.g., active layer 8, semiconductor layers 6 and 10), the epitaxial growth substrate may be partially or completely removed thereby allowing for the fabrication of the device structure illustrated in FIG. 1. In some embodiments, the plurality of semiconductor layers (e.g., layers 6 and 10) and the active layer 8 form interfaces that are oriented substantially parallel to a non-polar plane of the crystal structure (e.g., c-plane or a-plane of a wurtzite crystal structure). In other embodiments, the plurality of semiconductor layers (e.g., layers 6 and 10) and the active layer 8 form interfaces that are oriented substantially parallel to a semi-polar plane of the crystal structure.

One or more (e.g., all) of the device layers may be formed or one or more ZnO-based materials. In some embodiments, at least one of the active layer 8, the n-type semiconductor layer, and the p-type semiconductor layer may be formed of a ZnO-based semiconductor. The plurality of semiconductor layers (e.g., n-type and p-type semiconductor layers 6 and 10) may be formed of one or more ZnO-based semiconductors. The active layer 8 may be formed of one or more ZnO-based semiconductors. In embodiments where the entire semiconductor portion is formed of ZnO-based materials, each of the active layer 8, the n-type semiconductor layer, and the p-type semiconductor layer may be formed of one or more ZnO-based semiconductors. Alternatively, at least one layer of the semiconductor portion may be formed of one or more Group III-nitride semiconductors. For example, the plurality of semiconductor layers (e.g., layers 6 and 10) and/or the active layer may be formed of one or more Group III-nitride semiconductors.

It should be appreciated that since ZnO-based materials have a natural tendency to form multi-grain nanostructures or microstructures, electrical contacting of such structures may be problematic. In contrast, the formation of monocrystalline ZnO-based layer(s) may alleviate these problems while at the same time avoiding any defect-related problems associated with poly crystalline and/or amorphous ZnO-based layers. Furthermore, a textured monocrystalline layer, such as a textured monocrystalline ZnO-based layer may be employed in devices, such as light-emitting devices (e.g., LEDs), so as to facilitate light extraction or collection. A light-emitting emitting device (e.g., LED) including a textured layer, such as a textured light emission surface, may facilitate the extraction of light generated within the device structure (e.g., by the active layer) via the frustration of total internal reflection within the device structure.

In some embodiments, a light-emitting device includes at least one textured monocrystalline ZnO-based layer. In some embodiments, at least one of the active layer 8, the n-type semiconductor layer, and the p-type semiconductor layer comprises a textured monocrystalline ZnO-based layer. The plurality of semiconductor layers (e.g., n-type and p-type semiconductor layers 6 and 10) include at least one textured monocrystalline ZnO-based layer. Alternatively, or additionally, active layer 8 includes at least one textured monocrystalline ZnO-based layer. The plurality of semiconductor layers 6 and 10 and the active layer 8 may be deposited on a first side of an epitaxial growth substrate. The epitaxial growth substrate includes a second side opposite the first side of the substrate, where the second side of the substrate may be textured and may serve as a textured light emission surface, as described further below.

In some embodiments, the n-type semiconductor layer and/or the p-type semiconductor layer (e.g., layers 6 and/or 10) may have a refractive index of less than 2.3 at a light emission wavelength of the active layer 8. Such a refractive index may be achieved via the use of various ZnO-based materials, in contract to presently popular light-emitting device materials (e.g., GaN-based materials) that have larger a refractive index of about 2.5. For example, ZnO itself has a refractive index of about 2.1 at a wavelength of about 450 nm. Such a low refractive index may provide a great advantage and greatly facilitate light extraction efficiency.

Semiconductor layer 6 may be an n-type layer and semiconductor layer 10 may be a p-type layer. Alternatively, semiconductor layer 6 may be a p-type layer and semiconductor layer 10 may be an n-type layer. The thickness of semiconductor layer 6 and/or semiconductor layer 10 may range from about 0.5 microns to about 3 microns, however any other suitable thickness may also be used. Doping of semiconductor layer 6 and/or semiconductor layer 10 may be achieved with various dopant elements for ZnO-based materials, as described in detail below. For ZnO-based materials, doping one or more suitable Group IA, IB, VA and/or VB elements, such as K, Au, Ag, N, P As, Sb and/or other appropriate elements, may be used to achieve p-type conductivity. For ZnO-based materials, doping one or more suitable Group III elements (e.g., B, Al, Ga, In, and/or Tl) and/or Group VII elements (e.g., F, Cl, Br, I) may be used to achieve n-type conductivity. The doping concentration of part or all of semiconductor layer 6 and/or semiconductor layer 10 may range between from about 10¹⁶ cm⁻³ to about 10²⁰ cm⁻³, however any other suitable doping concentration may be used.

One or both of semiconductor layer 6 and semiconductor layer 10 includes ZnO-based materials, such as one or more ZnO-based epitaxial layers. In some embodiment, the entire semiconductor layer 6 and/or the entire semiconductor layer 10 are formed of one or more ZnO-based materials, such as one or more ZnO-based epitaxial layers. Such materials include ZnO itself and/or ZnO-based alloys including Mg, Ca, Be, Sr, Ba, Cd, Se, Te, and/or S.

In some embodiments, semiconductor layer 6, semiconductor layer 10, active layer 8, and/or transparent conducting layer 12 may be textured. In some embodiments, semiconductor layer 6, semiconductor layer 10, active layer 8, and/or transparent conducting layer 12 includes a textured monocrystalline layer. A textured surface morphology of a layer may be formed during and/or after deposition of the layer. Texturing a layer during deposition may involve the use of appropriate deposition conditions, such as temperature, so as to produce a textured layer during the deposition process. Texturing a layer after deposition may involve roughening (e.g., via one or more wet and/or dry etches) and/or patterning (e.g., via a lithography process) the deposited layer.

Active layer 8 includes one or more layers having a different bandgap than the adjacent semiconductor layers, thereby forming a double heterostructure. Semiconductor layer 6 and semiconductor layer 10 may provide carrier confinement due to bandgap differences with the active layer. For example, the bandgap of semiconductor layers 6 and 10 may be larger than the bandgap of one or more layers in the active layer 8 (e.g., quantum wells and/or barrier layers). Such a configuration may also ensure that layers 6 and 10 do not substantially absorb light emitted by active layer 8.

Active layer 8 may be a bulk layer or includes one or more quantum wells that may be separated by barrier layers. Active layer 8 may be a single quantum well structure or a multiple quantum well structure (e.g., including two quantum wells, three quantum well, four quantum wells, etc.). In some embodiments, active layer 8 includes one or more ZnO-based semiconductors having bandgaps that can emit the desired wavelength of light under application of an electrical current to the light-emitting device (e.g., via device electrodes). In some embodiments, one or more ZnO-based semiconductors in the active layer (e.g., forming the quantum wells) have a bandgap of less than about 3 eV (e.g., less than about 2.8 eV, less than about 2.5 eV, less than about 2.3 eV) and thereby can generate visible light (e.g., violet light, blue light, and/or green light wavelengths) during device operation.

In some embodiments, the active layer 8 (e.g., quantum wells in the active layer) includes a ZnO-based material including Cd, Se, and/or Te. Such elements may facilitate the modification (e.g., lowering) of the bandgap so as to provide a desired wavelength for the emitted light (e.g., visible light such as blue light). The Cd, Se, and/or Te atomic fraction may be less than about 0.3 and/or may be greater than about 0.05. Such alloys may enable visible light generation (e.g., ranging from about 400 nm to about 700 nm).

Barrier layers for the quantum wells may be formed of a material having a larger bandgap that the quantum wells, for example, any suitable ZnO-based material may be used that has such a bandgap. For example, ZnO itself or any suitable ZnO-based materials including Mg, Ca, Be, Sr, Ba, Cd, Se, Te, and/or S may be used as a barrier layer material for one or more of the quantum well barrier layers. Barrier layers may be p-type, n-type, and/or intrinsic layers.

In some applications, the active layer 8 includes a ZnO-based material having a bandgap corresponding to UV light (e.g., UV-A, UV-B, or UV-C). For example, quantum wells may be formed with ZnO, ZnMgO, ZnBeO, ZnSrO and/or ZnCaO to produce light emission at or above the bandgap energy of ZnO (e.g., greater than about 3.37 eV). In such devices, semiconductor layer 6 and/or semiconductor layer 10 includes a ZnO-based alloy having a higher bandgap than the ZnO-based material in the active layer (e.g., quantum wells in the active layer).

In some embodiments, the active layer 8, the n-type semiconductor layer and/or the semiconductor p-type layer (e.g., semiconductor layers 6 and 10) may be monocrystalline layers having a dislocation density of less than about 10⁶ cm⁻² (e.g., less than about 10⁵ cm⁻², less than about 10⁴ cm⁻², less than about 10³ cm⁻², less than about 10² cm⁻²), as measured using etch pit density methods. Alternatively, the active layer 8, the n-type semiconductor layer and/or the semiconductor p-type layer (e.g., semiconductor layers 6 and 10) may be monocrystalline layers having a dislocation density of less than about 5×10⁸ cm⁻² (e.g., less than about 10⁸ cm⁻², less about 10⁷ cm⁻²). In some embodiments, the active layer 8, the n-type semiconductor layer and/or the semiconductor p-type layer (e.g., semiconductor layers 6 and 10) may be have a stacking fault density of less than about 10⁵ cm⁻¹ (e.g., less than about 10⁴ cm⁻¹, less than about 10² cm⁻¹, less than about 1 cm⁻¹). Such low dislocation densities and/or stacking fault densities may be achievable as a result of the deposition of epitaxial layers having a composition that may be substantially lattice-matched to the substrate. The epitaxial layers may have a lattice mismatch with the epitaxial growth substrate of less than about 2.5% (e.g., less than about 2%, less than about 1%, less than about 0.5%, less than about 0.25%). For example, ZnO-based epitaxial layers, such as ZnO itself and/or ZnO-based alloys including Mg, Ca, Be, Sr, Ba, Cd, Se, Te, and/or S with a suitable atomic fraction, may be deposited on a ZnO substrate so as to achieve a low lattice mismatch with the substrate. Single crystal bulk ZnO substrates may have a dislocation density of less than about 10² cm⁻², as measured using etch pit density methods, thereby providing a low dislocation density baseline.

In some embodiments, transparent conductive layer 12 may be formed of one or more materials (e.g., ZnO-based materials) having a bandgap larger than the bandgap of the active layer or larger than the bandgap of quantum wells in the active layer, thereby minimizing the absorption of generated light. Transparent conductive layer 12 may be formed of one or more materials (e.g., ZnO-based materials) having a bandgap larger than the bandgap of semiconductor layer 6 and/or semiconductor layer 10 (e.g., cladding and/or contact layers of the light-emitting device).

In some embodiments, transparent conductive layer 12 may be formed of a transparent conductive oxide. Examples of transparent conductive oxides include ZnO-based materials, In₂O₃, indium tin oxide (ITO), or any combination thereof. In one embodiment, the transparent conductive layer 12 includes a ZnO-based material including In, Ga, and/or Al. The concentration of the In, Ga, and/or Al may range from dopant levels (e.g., greater than 10¹⁸ cm⁻³, greater than 10¹⁹ cm⁻³, greater than 10²⁰ cm⁻³) to alloying atomic fractions (e.g., less than about 40%, less than about 20%, less than about 30%, less than about 10%), preferably between about 0.1% and about 10%. Transparent conductive layer 12 may have any suitable thickness, with a typical thickness ranging from between about 0.1 microns and about 3 microns, and a preferred thickness of about 1 microns. In some embodiments, the transparent conductive layer, such as a transparent conductive oxide, may have a thickness and absorption coefficient so as to exhibit light transmittance of greater than about 60% (e.g., greater than about 70%, greater than about 80%, greater than about 90%) at a wavelength emitted by the active layer. In some embodiments, the transparent conductive layer, such as a transparent conductive oxide, has a resistivity of less than about 10⁻² Ωcm (e.g., less than about 10⁻³ Ωcm) for an n-type layer and less than about 1 Ωcm (e.g., less than about 10⁻¹ Ωcm) for a p-type layer.

In some embodiments, transparent conductive layer 12 may be formed of a monocrystalline transparent conductive oxide layer. The monocrystalline transparent conductive oxide layer may be formed of a ZnO-based material. The monocrystalline transparent conductive oxide layer may be disposed adjacent semiconductor layer 6 (e.g., the n-type semiconductor layer or the p-type semiconductor layer) and configured to provide current spreading to the semiconductor layer on which it is disposed.

It should be appreciated that transparent conductive oxides are typically deposited as polycrystalline or amorphous films (e.g., via sputtering), whereas in some embodiments described herein, the transparent conductive oxide takes the form of a monocrystalline layer. Epitaxial deposition processes, such as epitaxial deposition processes described herein may be used to form monocrystalline transparent conductive oxides, such as ZnO-based transparent conductive oxides. The monocrystalline character of a transparent conductive layer may be of importance in the device fabrication process, since the transparent conductive layer 12 may be a buried epitaxial layer formed during the epitaxial deposition process, as described further below. As such, the crystal quality of the transparent conductive layer 12 may impact the crystal quality of device layers deposited thereon, as described in further detail in relation to a fabrication process that may be used to produce a device such as that shown in FIG. 1.

In some embodiments, a ZnO-based monocrystalline transparent conductive oxide includes a monocrystalline ZnO-based compound including Al, In, and/or Ga. Such a monocrystalline transparent conductive oxide may have an n-type conductivity since Al, In, and/or Ga may act as donors for a ZnO-based material. In some embodiments, a ZnO-based monocrystalline transparent conductive oxide includes a monocrystalline ZnO-based compound including K, Au, and/or Ag. Such a monocrystalline transparent conductive oxide may have a p-type conductivity since K, Au, and/or Ag may act as acceptors for a ZnO-based material.

In some embodiments, transparent conductive layer 12 includes a monocrystalline transparent conductive oxide layer having a dislocation density of less than about 10⁶ cm⁻² (e.g., less than about 10⁵ cm⁻², less than about 10⁴ cm⁻², less than about 10³ cm⁻², less than about 10² cm⁻²), as measured using etch pit density methods. Such a low dislocation density for a monocrystalline transparent conductive layer is achievable as a result of the deposition of epitaxial layers that are substantially lattice-matched to the substrate. The epitaxial layers may have a lattice mismatch with the substrate deposition surface of less than about 2.5% (e.g., less than about 2%, less than about 1%, less than about 0.5%, less than about 0.25%). For example, a ZnO-based transparent conductive layer having a suitable composition may be deposited on a ZnO substrate so as to achieve low lattice mismatch with the substrate.

In some embodiments, transparent conductive layer 12 may have a textured surface so as to facilitate light extraction. In some embodiments, transparent conductive layer 12 may comprise a textured monocrystalline layer. In some embodiments, the transparent conductive layer 12 may comprise a textured monocrystalline ZnO-based layer. The textured monocrystalline layer may be a textured monocrystalline transparent conductive oxide layer. A textured surface morphology of a layer, such as transparent conductive layer 12, may be formed during and/or after deposition of the layer, as described in further detail below.

Transparent conductive layer 12 may extend the entire surface of semiconductor layer 6 or may extend over a portion of semiconductor layer 6. In some embodiments, a first portion of semiconductor layer 6 is covered by transparent conductive layer 12 and a second portion of semiconductor layer 6 is not covered by transparent conductive layer 12. For example, transparent conductive layer 12 may be arranged in a suitable geometrical layout, for example a grid layout, a cross layout, fingered layout, an inter-digitated layout, or any other pattern.

Alternatively or additionally, a thin metal layer may be disposed over a portion or all of semiconductor layer 6 in any suitable geometrical layout and may serve as a current spreading layer. A bonding pad may be disposed over a portion of the thin metal layer. The thin metal layer may have a thickness of about 1 nm to about 100 nm and may be semi-transparent, preferably less than about 10 nm. The thin metal layer may be formed of a semi-transparent metal such as Pd, Pt, Pd/Au, Ni, NiO, Ni/NiO, Ni/Au, NiO/Au, or any other suitable metal(s) or any alloy thereof. Suitable metal layer(s) may be selected to provide an Ohmic contact with the adjacent semiconductor layer. For example, a thin semi-transparent metal layer including Ni, such as Ni, NiO, or NiO/Ni, may provide for an Ohmic contact with a p-type ZnO-based material layer. A thin semi-transparent metal layer including Ti and/or Cr may provide an Ohmic contact with an n-type ZnO-based material layer. In some embodiments, a thin metal layer may be disposed over a portion or all of transparent conductive layer 12.

During operation of a light-emitting device, such as the device of FIG. 1, electrical power may be injected to the active layer 8 via electrodes 14 and 16. Electrons and holes may recombine radiatively at the active layer 8 thereby generating light, illustrated by dashed lines in the drawings. Light generated in the active layer may be emitted towards the textured light emission surface 9 or the electrode 16. Light impinging on the textured light emission surface 9 may be extracted at least partially via the textured light emission surface 9, and some of the impinging light may be reflected back. Reflective surface 5 may reflect the light back toward the textured light emission surface 9. The light may undergo multiple passes before extraction is complete, and the absence or reduced thickness of the epitaxial growth substrate may eliminate or reduce substrate absorption that would otherwise impede the light output of the device. A majority of the generated light (e.g., greater than about 50%, greater than about 60%, greater than about 70%, greater than about 80%, greater than about 90%) may be extracted after multiple passes (e.g., less than about 6 passes, less than about 5 passes, less than about 4 passes, less than about 3 passes), and a remainder of the light may be absorbed within layers in the structure.

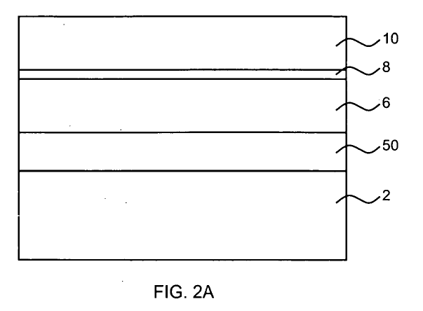

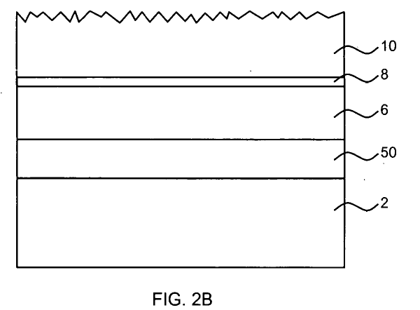

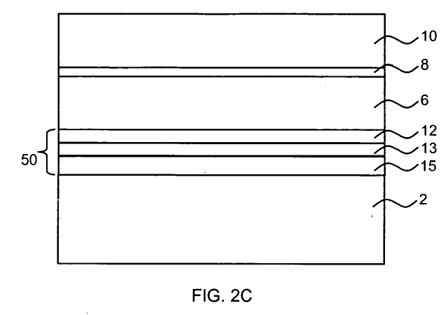

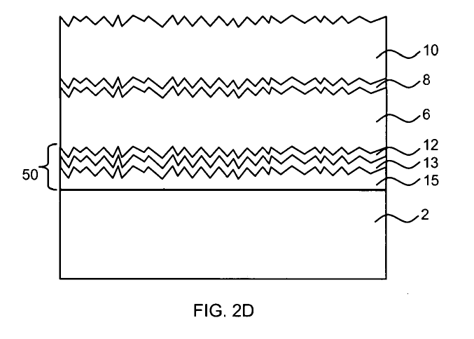

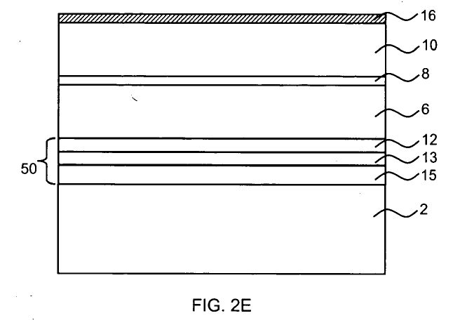

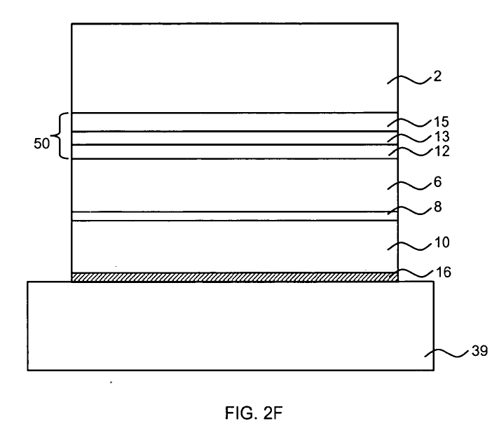

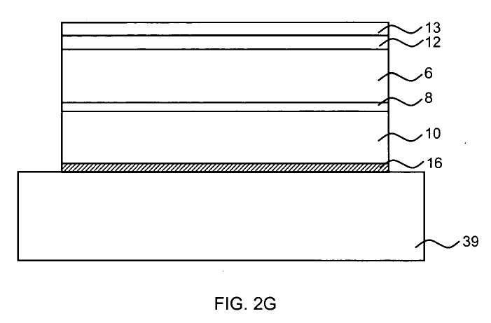

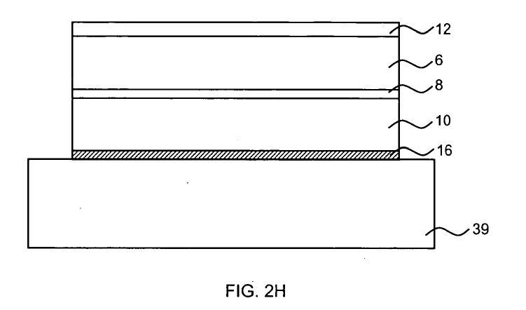

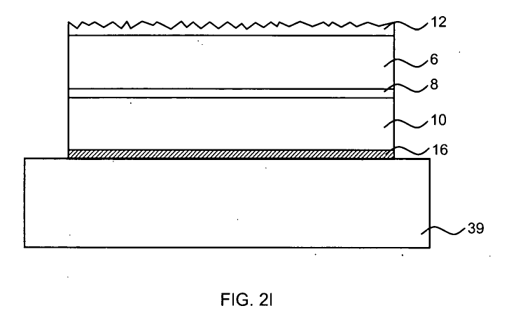

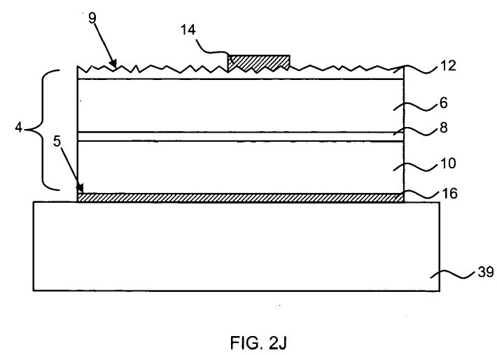

FIGS. 2A-2J illustrate intermediate structures that may be formed during the fabrication of device structures provided herein, such as the device shown in FIG. 1. The method includes providing a substrate 2 on which layers may be deposited, so as to form a layered structured as shown in the cross-sectional view of FIG. 2A. A portion of the layered structure may then be transferred to a sub-mount, as described herein.

Substrate 2 may be a ZnO, MgO, III-nitride (e.g., GaN, AN), sapphire, SiC, silicon, ScAlMg substrate, or any other suitable substrate. In some embodiments, the substrate may be a single crystal substrate thereby enabling the deposition of epitaxial layers thereon. The substrate may be electrically conductive (e.g., n-type or p-type), electrically insulating, or electrically semi-insulating. Substrate 2 may be optically transparent (e.g., to the wavelength of light emitted by the active layer and/or to all visible wavelengths). In some embodiments, the substrate comprises a ZnO-based material (e.g., ZnO, ZnMgO, or any other ZnO-based alloy). Examples of such substrates include a ZnO single crystal substrate, a substrate including a layer of ZnO disposed on (e.g., deposited on and/or wafer bonded to) another material such as a sapphire base substrate or a glass base substrate, or any other substrate that includes a ZnO-based material.

The substrate may have any crystal orientation so that the deposition surface exposes a desired crystal plane. In some embodiments, the substrate deposition surface is orientated such that the deposition surface is substantially non-polar (e.g., m-plane, a-plane). Alternatively, the substrate deposition surface is orientated such that the deposition surface is substantially semi-polar. In yet other embodiments, the substrate deposition surface is orientated such that the deposition surface is substantially polar (e.g., c-plane).

In some embodiments, the substrate has a hexagonal crystal structure (e.g., wurtzite). For example, the substrate may be a substrate having a ZnO or III-nitride surface layer or a ZnO or III-nitride single crystal substrate. The substrate may have a deposition surface oriented substantially parallel to a c-plane of the hexagonal crystal (e.g., with no off-cut or vicinal to the c-plane), which may provide for a substantially polar deposition surface. Alternatively, the substrate may be oriented substantially parallel to an m-plane or an a-plane of the hexagonal crystal (e.g., with no off-cut or vicinal to the m-plane or a-plane), which may provide for a substantially non-polar deposition surface. Alternatively, the substrate may be oriented substantially parallel to semi-polar crystal planes such as (11-10), (10-1-1), (10-12), (10-1-2), (11-2-1), (11-21), (11-2-2), and (11-22) planes or equivalent planes, which may provide for a semi-polar deposition surface.

Although substrate 2 may be completely removed in some device structures provided herein, in other device structures, a portion of substrate 2 may be retained in the final device. In light-emitting devices where a portion of substrate 2 is present in the final device, it is preferred to substantially match the refractive index of substrate 2 and the epitaxial device layers so as to avoid light trapping in the epitaxial device layers or the substrate 2. Thus, in some embodiments, the substrate has a refractive index that is substantially the same (i.e., having a refractive index difference of less than about±0.3) as the refractive index of the n-type semiconductor layer and the p-type semiconductor layers. In some embodiments, the substrate has a refractive index of greater than 1.9 at a light emission wavelength of the active layer. Such a substrate refractive index should be contrasted with the refractive index of a sapphire substrate, used for many GaN-based LEDs, that has a refractive index of about 1.8. In some embodiments, the substrate has a refractive index of less than 2.6 (e.g., less than about 2.3) at the light emission wavelength of the active layer. Such a substrate refractive index should be contrasted with the refractive index of SiC substrates, also used for GaN-based LEDs, that has a refractive index of about 2.7.

In some embodiments, the substrate may comprise a smooth surface over which the active layer, the n-type semiconductor layer and the p-type semiconductor layer are disposed. For example, a smooth surface may have a root-mean-square (RMS) roughness of less than about 5 nm (e.g., less than about 2 nm, less than about 1 nm). In some embodiments, the deposition surface of substrate 2 may be textured which may impart texturing to layers deposited thereon. Alternatively, both the deposition surface and the backside of the substrate may be textured. Texturing of the substrate may be achieved via a texturing etch and/or patterning. For example, when a ZnO substrate is utilized, a texturing etch that may be used to texture the substrate includes HCl, a mixture of HCl and H₃PO₄, acetic acid, or mixtures thereof

The method includes depositing intermediate layer 50 on substrate 2. Intermediate layer 50 includes one or more layers that may have different compositions, doping levels, and conductivity-type (e.g., n-type or p-type). Some or all of the layers that form intermediate layer 50 may be monocrystalline layers, and thereby provide a high quality surface on which subsequent epitaxial layers may be deposited. Intermediate layer 50 includes a buffer layer, an etch-stop layer, a transparent conductive layer, and/or other suitable layers that may facilitate epitaxial deposition and/or device fabrication. In some embodiments, one or more of the buffer layer, the etch-stop layer, and the transparent conductive layer may be the same layer. First conductivity-type semiconductor layer 6 (e.g., n-type or p-type), second conductivity-type semiconductor layer 10 (e.g., p-type or n-type), and active layer 8 may be deposited on intermediate layer 50.

The deposition process utilized to deposited one or more of the layers (e.g., layers 50, 6, 8, and/or 10) includes using conventional techniques such as chemical deposition techniques (e.g., MOCVD, plasma CVD) and/or physical deposition techniques (e.g., MBE). In a preferred embodiment, layers 6, 8, 10 and optionally also layer 50 are deposited in a single deposition process, such as an MOCVD or MBE process. In one or more embodiments, one or more of the above-mentioned layers may be ZnO-based epitaxial layers (i.e., epilayers) deposited on substrate 2.

A ZnO-based epilayer may be deposited using conventional techniques such as chemical deposition techniques (e.g., MOCVD, plasma CVD), physical deposition techniques (e.g., MBE, pulsed laser deposition, plasma assisted PLD) and the like. The ZnO-based material, in the form of an epilayer or otherwise, may be p-doped, n-doped, undoped, or compensated, as desired for each specific layer of the structure.

U.S. patent application Ser. No. 11/551,058, entitled “Zinc Oxide Based II-VI Compound Semiconductor Layers with Shallow Acceptor Conductivities and Methods of Forming Same,” which is hereby incorporated in its entirety by reference, discloses chemical vapor deposition fabrication techniques that enable the use of ZnO compounds in various applications. The fabrication techniques overcome difficulties relating to reliably fabricating p-type ZnO materials with sufficiently high concentrations of relatively shallow acceptor impurities operating as p-type dopants. The same methods used for p-type doping may also be used to prepare n-type ZnO by selection of the appropriate n-type dopants. An n-type ZnO may be prepared by using dopants including Al, Ga and In, or other appropriate elements. By way of example, ZnO may be doped with In at concentrations ranging from approximately 1×10¹² to 1×10²⁰ cm⁻³. The same fabrication techniques may be used to prepare n-type, p-type, undoped, and/or compensated ZnO alloys. In some embodiments, epitaxial layers of ZnO-based materials may be doped with p-type species such as Ag, Au and K and which may have as much as 50% acceptor activation in ZnO. In a similar manner, epitaxial layers of ZnO-based materials may be doped with n-type species such as aluminum, gallium or indium.

In some embodiments, the processing techniques for incorporating p-type dopants includes implanting the silver, potassium and/or gold dopants into the ZnO-based compound semiconductor layer at dose levels of greater than about 1×10¹³ cm⁻² and, for example, in a range from about 1×10¹³ cm⁻² to about 1×10¹⁵ cm⁻². This implanting step may be performed as a single implanting step or as multiple implanting steps, which may be performed at multiple different implant energy levels to thereby yield multiple implant peaks within the layer. An annealing step may then be performed to more evenly distribute and activate the dopants and repair crystal damage within the layer. This annealing step includes annealing the ZnO-based compound semiconductor layer at a temperature in a range from about 250° C. to about 2000° C., in an ambient (e.g., chemically inert ambient) having a pressure in a range from about 25 mbar to about 7 kbar. In certain applications, it may be preferable to perform the annealing step at a temperature in a range from about 700° C. to about 700° C., in an oxygen ambient environment having a pressure of about 1 atmosphere. Similar ion implantation and anneal processes can be used for n-type dopants.

In some embodiments, a p-type ZnO-based compound semiconductor layer may be formed using an atomic layer deposition (ALD) technique, e.g. a deposition technique that includes exposing a substrate to a combination of gases. This combination includes a first reaction gas containing zinc at a concentration that is repeatedly transitioned (e.g. pulsed) between at least two concentration levels during a processing time interval, and a second reaction gas containing oxygen and a p-type dopant gas containing at least one p-type dopant species selected from a group consisting of silver, potassium, gold, or an n-type dopant gas, as appropriate. A concentration of oxygen in the second reaction gas may be repeatedly transitioned between at least two concentration levels. In particular a concentration of zinc in the first reaction gas and a concentration of oxygen in the second reaction gas may be transitioned in an alternating sequence so that relatively high zinc concentrations in the first reaction gas overlap with relatively low oxygen concentrations in the second reaction gas and vice versa.

Methods of forming a p-type ZnO-based compound semiconductor layer may also include using an iterative nucleation and growth technique. This technique includes using an alternating sequence of deposition/growth steps that favor c-plane growth (i.e., vertical growth direction, which causes nucleation) at relatively low temperatures interleaved with a-plane growth (i.e., horizontal growth direction, which causes densification) at relatively high temperatures to coalesce the layer. Iterative nucleation and growth includes depositing a plurality of first ZnO-based compound semiconductor layers at a first temperature in a range from about 200° C. to about 600° C. and depositing a plurality of second ZnO-based compound semiconductor layers at a second higher temperature in a range from about 400° C. to about 900° C. These first and second ZnO-based compound semiconductor layers are deposited in an alternating sequence so that a composite layer is formed.

Still other methods of forming a p-type ZnO-based compound semiconductor layer include exposing the substrate to a combination of a first reaction gas containing zinc, a second reaction gas containing oxygen and a p-type dopant gas containing at least one p-type dopant species selected from a group consisting of silver, potassium and gold, while simultaneously transitioning a temperature of the substrate between at least two temperatures. These two temperatures includes a first lower temperature in a range from about 200° C. to about 600° C. and a second higher temperature in a range from about 400° C. to about 900° C.

According to aspects of these embodiments, the concentration of the p-type dopant species in the p-type dopant gas is repeatedly transitioned between two concentration levels while the temperature of the substrate is also being transitioned between the two temperatures. In particular, the concentration of the p-type dopant species in the p-type dopant gas is transitioned in an alternating sequence relative to the transitioning of the temperature of the substrate so that relatively high concentrations of the p-type dopant species in the p-type dopant gas overlap with relatively low temperatures of the substrate and vice versa. Alternatively, the concentration of the p-type dopant species in the p-type dopant gas is transitioned so that relatively high temperatures of the substrate overlap with a timing of relatively high concentrations of the p-type dopant species in the p-type dopant gas.

In some embodiments, one or more ZnO-based compound semiconductor layer(s) may be formed on a substrate using a chemical vapor transport technique (e.g., MOCVD). This technique includes transporting concentrations of a plurality of reaction gases in a carrier gas towards a substrate that is exposed to an ambient at growth temperature(s) between 300° C. and 1000° C. The pressure of the ambient is held in a range from about 20 Torr to about 76 Torr. By varying the reaction gases and/or their flow rates, one or more semiconductor layers (e.g., monocrystalline semiconductor layers) having desired compositions may be deposited on the substrate. Controlling the reaction can be used to control the thickness of each semiconductor layer. Reaction gases includes diethylzinc for Zn, and oxygen gas for O. Alternative oxygen reaction gases includes carbon dioxide, nitrous oxide, and/or nitrogen dioxide. Other reaction gases may be used for additional elements present in the desired semiconductor layer, such as cyclopentadiethylmagnesium for Mg, diethylcadmium for Cd, di-tertiary-butylselenium for Se, and other reaction gases known to those of ordinary skill in the art. Other reaction gases that may be employed includes ethyl chloride as an n-type dopant gas of Cl, plasma N2 or the like as a p-type dopant gas, or any other reaction gases known in the art for providing the desired elements for deposition.

In some embodiments, a condensed matter source may be used for some doping and/or alloying elements (e.g., Ag, Au, K) to circumvent limited availability of some volatile species using conventional metalorganic transport temperatures (e.g.,≦30° C.) and equipment. When using a condensed matter source, the source can be converted to a gas prior to transport. A condensed matter source includes a source in a solid phase, a liquid phase or a semisolid phase, such as a gel. A bubbler or heater containing the condensed matter source may be heated to above room temperature in order to convert the source to the gas phase.

The condensed matter source may, preferably, include non-halogenated and non-silylated complexes, or includes halogenated or silylated complexes. When using non-halogenated or non-silylated complexes, the material should have sufficient vapor pressure at reasonable elevated temperatures. For example, non-halogenated or non-silylated solid sources of Ag, Au and K may have a vapor pressure ranging from about 10⁻⁵ to about 10³ torr between about 30° C. and about 200° C. Generally, the sublimation of Au and K occurs at higher temperatures relative to Ag sublimation because of much lower volatility of their ligands.

Examples of some non-halogenated and non-silylated precursors that may be used for the source are listed below in Table 1 and some halogenated or silylated precursors that may be used are listed below in Tables 2 and 3, although others may be used.

TABLE 1
Non-halogenated and non-silylated precursors of Ag, Au and K

| Name | Variation |
|---|---|
| (R) silveracetylacetonate | R = Alkene and Alkyl |
| Silver Pivilate | |
| Silver trimethylacetate | |
| Dimethyl 1-2,4 pentadionate-Au | |
| (N,N″-diisopropylacetamindinato)Silver | Ag(i-PrNC(CH₃)N i-Pr) |
| Potassium Butoxide | |
| Triethylphosphine-Au-1-Diethyl- | |
| dithiocarbamate | |
| Dipivaloylmethanoatopotassium(KDPM) | |

TABLE 2
List of Halogenated or Silylated Silver and Gold Precursors

| Name | Variations | | |
|---|---|---|---|
| α-silver | α= | (β-diketonato) | |
| (bistrimethylsilyl)acetylene | | Hfac = hexafluoroacetyl | |
| | | Ttfac | |
| | | Btfac | |
| | | fod | |
| α-silver-vinyltriethlysilane | α= | Hfac | |
| α-silver-trialkylphosphine | α= | | (Cyclopentadienyl) |
| Ag(Cp)(PR₃) | | | (13-diketonato) |
| | | Hfac | |
| | | fod | |
| | | R= | Hydrocarbon e.g. |
| | | | Methyl group |
| | | | Ethyl group |

| | |
|---|---|
| Silver trifluoroacetate | Ag(COOCF₃) |
| Silver pentafluoropropionate | Ag(C₂F₅COO) and |
| | Ag(C₂F₅COO)PMe₃ |
| Dimethyl(1,1,1, trifiuoro-2-4 | |
| pentadionate)Au | |
| Dimethyl(1,1,1-5,5,5, | |
| hexafluoro-2-4 | |
| pentadionate)Au | |
| Triethylphosphine-Au-Chloride | |

TABLE 3
List of Halogenated or Silylated Potassium Precursors

| Name | Variations |
|---|---|
| Potassium Hexafluorogermanante | K₂GeF₆ |
| Potassium Hexafluorosilicate | K₂SiF₆ |
| Potassium HexamethylDisilazide | KSi(CH₃)₃NSi(CH₃)₃ |
| Potassium Trimethlysilanolate | KOSi(CH₃)₃ |
| Potassium VinlyDImethlySilanolate | KOSi(CH₃)₂CHCH₂ |

For example, when using silver atoms for the p-type dopant and/or an alloying element, the vapor pressure of the silver-based condensed matter source or precursor may typically be between at least about 10⁻⁵ to 10³ torr. The conversion of the silver-based precursors may be achieved by heating the bubbler or heater that contains one or more selected compounds (e.g., compounds containing Ag, Au, or K) to at or above the compound's sublimation temperature, but below its decomposition temperature. For example, for some silver-based compounds, the sublimation temperature may be between about 30° C. to about 205° C. and the decomposition temperature may be between about 80° C. to about 300° C. For instance, when using silver trifluoroacetate (CF₃COOAg) as the precursor, the heater may be uniformly heated to an elevated temperature of about 60° C. (or higher) to ensure that significant vapor pressure of the precursor (e.g.,≧10⁻⁵ torr) is achieved even though the actual sublimation temperature of CF₃COOAg commences at around 30° C. in air. Similarly, when using silver trialkyphosphine-acetylacetonate (AcAcAgP₃) as the precursor, the heater may be heated to a temperature of about 180° C. (or higher) to ensure that significant vapor pressure of the precursor (e.g.,≧10⁻¹ torr) is achieved even though the actual sublimation temperature of AcAcAgP₃ commences at around 80° C. in air. As known to those skilled in the art, the sublimation temperatures may be marginally different in a vacuum.

To form a ZnO-based material layer, a reaction gas comprising zinc may be provided from a zinc-based source, a reaction gas comprising oxygen may be provided from an oxygen-based source, and other one or more other reactions gases supplying other elements (e.g., alloying and/or doping elements) desired in the ZnO-based material. The zinc-based source and the oxygen-based source are typically supplied in the gas phase, although the source may be in a solid, liquid, or semisolid phase.

Reaction gases including alloying and/or dopant atoms may be transported to one or more substrates located within a reactor chamber. As known to those skilled in the art, the substrate may be a wafer processed in a variety of ways and includes a variety of materials. For ZnO-based films, the substrate preferably is a ZnO substrate (e.g., a single crystal ZnO substrate), although other materials may be used, as previously described. As previously stated, the use of a ZnO substrate provides growth conditions for ZnO-based device layers that allow for dislocation densities to be kept lower than about 10⁶ cm⁻² and improve resultant device performance.

Transport of gas species converted from condensed matter sources may be achieved by heating gas lines to an elevated temperature in order to limit or prevent condensation of the converted species during transport prior to delivery into a reactor chamber. The elevated temperature should be at least the minimum temperature of actual conversion/sublimation (e.g., 30° C. in the case of CF₃COOAg, 80° C. in the case of AcAcAgP₃) and preferably higher. For example, the elevated temperature gas lines may be maintained at approximately the same temperature as the bubbler (e.g., 60° C. in the case of CF₃COOAg, 180° C. in the case of AcAcAgP₃) or higher. For instance, the heated gas lines may be maintained at about 190° C. in the case of AcAcAgP₃.

An inert gas, such as argon, may be supplied into the heated bubbler through an inlet port via gas lines and allowed to exit through an outlet port into the heated gas lines. The inert gas may or may not be heated to an elevated temperature in gas lines prior to entering the heater. The elevated temperature gas transport lines may have valves and gauges that utilize special seals (e.g., such as polyimide and stainless steel), which may enable the flow regulation of the transported species within the temperature range of interest. Gas lines transport the second gas and the third gas, respectively, to the reactor chamber. The elevated temperature gas lines may be separate from the gas lines used from transporting the reaction gases of other elements (e.g., Zn and O₂) to prevent any premature reactions.

As is known by those skilled in the art, the deposition process may be conducted in the reactor chamber where the reaction gases may be combined. One or more additional gases may also be used, such as multiple organometallic precursors, reaction gases, inert carrier gases, etc.

Control of the process gas composition may be accomplished using mass-flow controllers, valves, etc., as known by those skilled in the art. The one or more substrates are typically heated to an elevated temperature in the reactor chamber. As the gases enter into the reactor, pyrolysis of the precursor complexes occurs either in the gas mixture or at the surface of the substrate when the gas mixture contacts the heated substrate surface.

In other embodiments, a ZnO-based compound semiconductor layer may be formed on a substrate using a molecular beam epitaxy technique. Using this technique, the desired elements to form the ZnO-based layer may be evaporated from one or more Knudsen cells to a substrate in a partial pressure of oxygen. For example, in the case of a ZnO-based material including Ag and/or Au elements (e.g., for doping and/or alloying), the Ag and/or Au may be evaporated from a first Knudsen cell concurrently with the evaporation of Zn from a second Knudsen cell in a partial pressure of oxygen. Additional Knudsen cell(s) can evaporate one or more other elements (e.g., Mg, Be, Ca, Sr, Ba, Cd, Te, Se, S, In, Al, Ga, or other elements) so as to form any desired ZnO-based material on the substrate. The temperature of the substrate is typically held at a temperature of greater than about 300° C. and at pressures ranging from about 25 mbar to about 700 mbar.

Still further embodiments include using a physical vapor transport technique that includes transport of zinc to a substrate by evaporation, magnetron sputtering, flame hydrolysis deposition or sublimation. Alternatively, liquid phase epitaxy techniques and solvus-thermal incorporation techniques may also be used to form the ZnO-based compound semiconductor.

The above-mentioned techniques may be employed to produce structures and devices that employ n-type, p-type, undoped, and/or compensated ZnO-based materials (e.g., ZnO-based epilayers). These techniques use processing conditions that can yield a net p-type dopant concentration of greater than about 1×10¹⁷ cm⁻³ therein, for dopants having an acceptor ionization energy below about 355 meV. The processing conditions may also yield a dopant activation level of greater than about 10% for the dopants having the desired acceptor ionization energy.

FIG. 2B illustrates a cross-sectional view of an alternative layered structure similar to that illustrated in FIG. 2A except that the second conductivity-type layer 10 has a textured surface. A portion of this layered structure may then be transferred to a sub-mount, as described herein. The textured surface morphology of second conductivity-type layer 10 may be formed during and/or after deposition of the layer. Texturing second conductivity-type layer 10 during deposition may involve the use of appropriate deposition conditions, such as temperature, so as to produce a textured surface during the deposition process, as described further below. Texturing second conductivity-type layer 10 after deposition may involve roughening (e.g., via one or more wet and/or dry etches) and/or patterning (e.g., via a lithography process) the deposited layer. For example, when texturing of a ZnO-based layer is desired, a texturing etch that may be used includes HCl, a mixture of HCl and H₃PO₄, acetic acid, or mixtures thereof. In some embodiments, dilute HCl (e.g., HCl concentrations between about 0.1% and about 1% HCl in deionized water) may be used as a texturing etch. When using dilute HCl, etch times may range from about 5 seconds to about 2 minutes. Preferably, for a dilute HCl etch having an HCl concentration of about 0.5%, etch times may range from about 20 seconds to about 60 seconds. Addition of H₃PO₄ to the etch solution may provide increased surface texturing (e.g., increased peak-to-valley depth, increased RMS roughness). The textured surface morphology includes features (e.g., hexagonal features) such as pyramids and/or cones, where the features may have shapes at least partially determined by the crystal structure of the etched material (e.g., hexagonal crystal). The surface features may have sidewall angles ranging from about 25 degrees to about 75 degrees, typically about 45 degrees.

FIG. 2C illustrates a cross-sectional view of an alternative layered structure similar to that illustrated in FIG. 2A except that intermediate layer 50 includes a plurality of different layers. A portion of this layered structure may then be transferred to a sub-mount, as described herein. For example, intermediate layer 50 of the structure of FIG. 2C includes buffer layer 15 deposited on substrate 2, etch-stop layer 13 may be deposited on buffer layer 15, and transparent conducting layer 12 may be deposited on etch-stop layer 13.

Buffer layer 15 includes one or more layers and may facilitate or alter the character of layers deposited thereon. Buffer layer 15 includes one or more monocrystalline layers that may provide a template for the deposition of high quality monocrystalline layers thereon, which may as a result have low dislocation density. For example, buffer layer 15 may relieve any lattice mismatch between the substrate 2 and layers deposited on the substrate 2. For example, buffer layer 15 may be compositionally graded layer structure that alleviates lattice mismatch. In some embodiments, the buffer layer 15 may at least in part determine the surface morphology of layers deposited thereon. For example, buffer layer 15 may alter the surface texture of layers deposited thereon. The surface chemistry and/or energy of the buffer layer 15 may impact the surface morphology of the layers deposited on the buffer layer 15, thereby influencing the degree and/or character of surface texturing for the deposited layers. The buffer influence on the surface morphology of layers deposited thereon includes influence on the surface roughness, in-plane distance between surface peaks, depth of surface depressions, facet angles of surface peaks, and/or other morphology characteristics. In some embodiments, buffer layer 15 may be deposited so that it has a textured surface morphology.

In some embodiments, at least a portion of buffer layer 15 may be monocrystalline and thereby provide for suitable deposition surface on which monocrystalline layers may be epitaxially deposited thereon. Buffer layer 15 may be substantially lattice-matched to the underlying substrate so as to keep the dislocation density low. Buffer layer 15 may have a low dislocation density of less than about 10⁶ cm⁻² (e.g., less than about 10⁵ cm⁻², less than about 10⁴ cm⁻², less than about 10³ cm⁻², less than about 10² cm⁻²). The lattice mismatch between buffer layer 15 and the substrate deposition surface may be less than about 2.5% (e.g., less than about 2%, less than about 1%, less than about 0.5%, less than about 0.25%).

In some embodiments, buffer layer 15 includes one or more oxide-based layers (e.g., metal oxide layers), such as one or more ZnO-based layers. Buffer layer 15 may substantially influence the surface morphology of layers deposited thereon. In some embodiments, buffer layer 15 includes one or more layers comprising transition metals, for example transition metal oxides. Examples of transition metal oxides include oxides comprising Mn, Co, Mo, Fe, Ni, V, Cr, Ti, etc. such as ZnO-based materials including or more transition metals, such as ZnMnO, ZnCoO, ZnMoO, ZnFeO, ZnNiO, ZnVO, ZnCrO, ZnTiO or combinations thereof. The atomic fraction of the transition metal(s) in the buffer layer may range from dopant levels (e.g., greater than 10¹⁷ cm⁻³, greater than 10¹⁸ cm⁻³, greater than 10¹⁹ cm⁻³, greater than 10²⁰ cm⁻³) to alloying fractions (e.g., less than about 40%, less than about 30%, less than about 20%, less than about 10%), preferably between about 0.1% and about 10%.

In some embodiments, buffer layer 15 includes one or more layers comprising one or more Group III elements, for example one or more oxide layers, such as one or more Group III-oxide layers that may also include Zn (e.g., ZnAlO, ZnGaN, ZnInN, or alloys thereof). The atomic fraction of Group III elements in the buffer layers may range from dopant levels (e.g., greater than 10¹⁷ cm⁻³, greater than 10¹⁸ cm⁻³, greater than 10¹⁹ cm⁻³, greater than 10²⁰ cm⁻³) to alloying atomic fractions (e.g., less than about 40%, less than about 30%, less than about 20%, less than about 10%, less than about 5%), preferably between about 0.1% and about 10%. In some embodiments, buffer layer 15 includes one or more nitride layers, such as one or more Group III-nitride layers (e.g., GaN, AN, InN, or combinations thereof).

Buffer layer 15 may be electrically conductive or electrically non-conductive, and may be doped according to achieve desired electrical properties such as n-type or p-type conductivity. Buffer layer 15 may have a thickness of less than about 5 microns (e.g., less than about 2 microns, less than about 1 micron, less than about 500 nm, less than about 100 nm, less than about 10 nm). In some embodiments, the thickness of the buffer layer is less than the critical thickness for dislocation nucleation in the buffer layer. As is well known, the critical thickness depends on the lattice mismatch between the buffer layer and that of the underlying layer on which the buffer is deposited (e.g. the substrate).

Etch-stop layer 13 includes one or more suitable layers that may provide an etch-stop for subsequent substrate removal processes. At least one layer of the etch-stop layer 13 may have a relatively slow etch rate as compared to the underlying substrate 2 material etch rate, for a given etch solution utilized to remove the substrate. In some embodiments, etch-stop layer 13 includes one or more oxide-based layers, such as one or more ZnO-based layers. Etch-stop layer 13 includes one or more ZnO-based materials that include alloying elements such as Group II elements (e.g., Mg, Be, Ca, Sr, Ba, Cd, or other related elements), Group VI elements (e.g., Te, Se, S, or other related elements) or combinations thereof. Alternatively or additionally, etch-stop layer 13 includes one or more nitride layers, such as one or more Group III-nitride layers (e.g., GaN, AN, InN, or combinations thereof). Nitride layers may be preferred as etch-stop layers, since nitride-based materials tend to exhibit very slow etch rates in a variety of etching solutions. Thus, nitride layers may serve as highly effective etch-stops for processes that involve the removal of a substrate including a ZnO-based material, such as ZnO substrates or substrates including ZnO surface layer(s) on an underlying material (e.g., glass, sapphire).

Etch-stop layer 13 includes layers having suitable composition and/or doping levels and conductivity type (e.g., n-type, p-type, intrinsic) to provide a high selectivity to the given etch utilized to remove substrate 2, whereby the underlying substrate 2 material may be etched at a much faster rate than etch-stop layer 13. For example, the selectivity for the etch process that is used to remove the substrate may be greater than about 10 (i.e., etch rate of the substrate versus the etch rate of the etch-stop), greater than about 50, or greater than about 100. Etch-stop layer 13 may be a monocrystalline layer that may have a low dislocation density and that may exhibit uniform etching rates across the entire surface of the layer, thereby providing a uniform stop for a selective etching process that may be utilized to remove the substrate 2.

Transparent conducting layer 12 may be any suitable transparent conducting layer, as previously described, and may be incorporated, in part or in whole, into the final device structure. For example, as described in relation to the device shown in FIG. 1, transparent conducting layer 12 may serve as a current spreading layer for the light-emitting device.

FIG. 2D illustrates a cross-sectional view of an alternative layered structure similar to that illustrated in FIG. 2C except that a plurality of the layers are textured. A portion of this layered structure may then be transferred to a sub-mount, as described herein.

In some embodiments, layer deposition conditions (e.g., temperature and/or reactant gas ratios) may result in the deposition of one or more textured layers on the substrate, as illustrated in the cross-sectional view of FIG. 2D. In some embodiments, layer deposition conditions (e.g., substrate temperature and/or reaction gas super saturation ratios) may create a textured monocrystalline layer. The textured layer may be a textured oxide semiconductor layer (e.g., a ZnO-based layer). The textured layer may be a textured monocrystalline oxide semiconductor layer, such as a textured monocrystalline ZnO-based layer. A textured monocrystalline layer should be distinguished from nano-crystalline layers formed of a multi-grain collection of nanostructures, such as nanorod, polycrystalline layers, and amorphous layers.

Regarding the deposition of a textured monocrystalline layer (e.g., a ZnO-based layer), the crystallographic orientation of the substrate deposition surface may influence the surface morphology of the deposited layer. For example, in the case of a wurtzite substrate (e.g., ZnO substrate), deposition on non-polar crystal planes, semi-polar crystal planes, or polar crystal planes may influence the surface morphology of the deposited layer.

In some embodiments, for a substrate having a ZnO deposition surface that is substantially non-polar (e.g., m-plane, a-plane, or vicinal planes thereof), a textured surface morphology for the deposited layer (e.g., a ZnO-based layer) may be achieved with substrate temperatures ranging from about 400° C. to about 600° C. A CVD process (e.g., MOCVD) may be used to deposit the textured layer. Supersaturation ratios of Group VI to Group II elements (VI/II) in the reaction chamber, such as oxygen to zinc (O/Zn) in the case of ZnO deposition, may range from about 50 to about 5000. As known by those skilled in the art, the supersaturation ratio may be derived from the molarity, the vapor pressure, or the flow rate of the gases. The above-mentioned deposition conditions allow for the formation of a textured monocrystalline ZnO-based layer. The in-plane separation between peaks of the textured surface may range from about 50 nm to about 1000 nm and may depend on the specific deposition conditions. Similar texturing of ZnO-based layers can also apply to semi-polar ZnO deposition surfaces.

For example, for non-polar (e.g., m-plane, a-plane, or vicinal surfaces thereof) ZnO deposition substrates, MOCVD substrate temperatures of about 480° C. and VI/II supersaturation ratios of about 425 produced a ZnO textured monocrystalline layer having in-plane separation between peaks of the textured surface ranging from about 100 nm to about 200 nm. For these deposition conditions, the textured surface had a laminar-like surface morphology.

In a further example, for non-polar (e.g., m-plane, a-plane, or vicinal surfaces thereof) ZnO deposition substrates, MOCVD substrate deposition temperatures of about 600° C. and VI/II supersaturation ratios of about 425 can produce a ZnO textured monocrystalline layers. For these deposition conditions, the textured surface also had a laminar-like surface morphology.

In yet another example, for non-polar (e.g., m-plane, a-plane, or vicinal surfaces thereof) ZnO deposition substrates, MOCVD substrate temperatures of greater than about 750° C. and VI/II supersaturation ratios of about 425 failed to nucleate a ZnO epitaxial film.

In contrast, substantially smooth surfaces may be formed on non-polar (e.g., m-plane, a-plane, or vicinal surfaces thereof) ZnO substrates for MOCVD substrate temperatures greater than about 600° C. and less than about 750° C. and VI/II supersaturation ratios of about 425.

Reactant chemistry may play an important role in determining the surface morphology of a deposited layer. Various reactant gases may contribute to the formation of a textured or substantially smooth deposited layers. In the case of ZnO-based layer deposition, various MOCVD reactant sources of oxygen include O₂, O₃, NO₂, N₂O, H₂O, CH₃COOH, other oxygen-including sources, or mixtures of such sources. The particular oxygen source(s) used in the deposition process may influence the surface morphology of the deposited layer (e.g., a ZnO-based layer).

For example, when utilizing an O₂, NO₂, or N₂O oxygen source gas with VI/II supersaturation ratios ranging from about 200 to about 400, the deposited ZnO-based layer exhibited a highly textured surface morphology. For these deposition conditions, the textured surface also had a patch-like surface morphology where the patches had hexagonal-like outlines.

When utilizing a mixture of O₂ and N₂O (e.g., mixture ratio of about 1:1) or a mixture of O₂ and NO₂ (e.g., mixture ratio of about 1:1) with VI/II supersaturation ratios ranging from about 200 to about 400, the deposited ZnO-based layer exhibited a substantially smooth surface morphology.

For deposition processes (e.g., MOCVD) where a ZnO deposition substrate has a substantially polar deposition surface (e.g., c-plane or vicinal surfaces thereof), a textured or smooth surface morphology for the deposited layer (e.g., a ZnO-based layer) may be achieved with a single-step or multiple-step deposition process. A multiple-step deposition process (e.g., MOCVD) includes performing a first deposition step at a first temperature and a second deposition step at a second temperature higher than the first temperature, as previously described. The first and second deposition steps may then be repeated until a desired deposited layer thickness is achieved, as previously described for the iterative nucleation and growth process.

For deposition on a polar ZnO surface (e.g., c-plane or vicinal surfaces thereof), iterative nucleation and growth includes depositing a plurality of first ZnO-based layers at a first substrate temperature in a range from about 200° C. to about 600° C. and depositing a plurality of second ZnO-based layers at a second higher substrate temperature in a range from about 400° C. to about 900° C. The first and second ZnO-based layers may be deposited in an alternating sequence so that a composite layer is formed. In some iterative nucleation and growth processes, the VI/II supersaturation ratios may range from about 50 to about 5000, and in some such embodiments, the VI/II supersaturation ratios may range from about 100 to 500.

For deposition on a polar ZnO surface (e.g., c-plane or vicinal surfaces thereof), a single-step deposition process (e.g., MOCVD) may involve performing a growth process for substrate temperatures ranging from about 650° C. to about 900° C., depending on reaction chemistry. When using an O3 and/or NO2 reaction gas, single-temperature deposition of ZnO-based layers may be performed at temperatures ranging from about 650° C. to about 900° C. When using an O2 reaction gas, single-temperature deposition of ZnO-based layers may be performed at temperatures ranging from about 850° C. to about 900° C. Supersaturation ratios of Group VI to Group II elements (VI/II) in the reaction chamber, such as oxygen to zinc (O/Zn) in the case of ZnO deposition, may range from about 50 to about 5000, and in some such embodiments, the VI/II supersaturation ratios may range from about 100 to 500.

Returning to the fabrication process, any desired layered structure (e.g., layer structures shown in FIG. 2A, 2B, 2C, or 2D) may be utilized in subsequent portions of the process. In the following drawings, the process is illustrated for a layered structure including an intermediate layer 50 comprising buffer layer 15, etch-stop layer 13 and transparent conducting layer 12, however the process is not limited in this respect and any other suitable layered structure may be utilized.

FIG. 2E illustrates a cross-sectional view of a structure that may be formed after the formation of an electrode 16 on the surface of semiconductor layer 10. One or more layers, such as one or more metal layers, that may from electrode 16 may be deposited on the surface of semiconductor layer 10. Deposition of the metal layers may involve evaporations, sputtering, and/or any other suitable metal deposition process. Electrode 16 may be formed of any suitable materials (e.g., one or more metals) that may provide a suitable electrical contact (e.g., Ohmic contact) to the adjacent semiconductor, as previously described herein. As previously described, electrode 16 includes a reflective surface (e.g., a metal surface) that is configured to reflect light generated by the light-emitting device.

FIG. 2F illustrates a cross-sectional view of a structure that may be formed by attaching (e.g., bonding) the surface of electrode 16 (e.g., of the structure shown in FIG. 2E) to a sub-mount 39. Attachment may involve the application of heat and/or pressure to achieve a sufficiently strong bond to the sub-mount. In some embodiments, the attachment process may be such that electrode 16 forms an electrical connection to the sub-mount 39. For example, in some processes, electrode 16 includes a metal surface that is bonded to a metal surface of sub-mount 39. In some embodiments, an attachment material, which may be conductive or electrically insulating, may be provided between electrode 16 and sub-mount 39, for example a solder or a die-attach.

FIG. 2G illustrates a cross-sectional view of a structure that may be formed by the removal of substrate 2 (e.g., of the structure shown in FIG. 2F). Removal of the substrate may involve one or more process, such as grinding, polishing, chemical mechanical polishing (CMP), wet etching, dry etching (e.g., reactive ion etching), lift-off (e.g., using a release layer), ion-implantation-assisted defoliation (e.g., Smart-cut™ process). The removal process may be selective, timed, and/or controlled via a feedback measurement (e.g., measurement of remaining layer thickness or surface properties such as refractive index). Complete or partial removal of substrate 2 may be achieved using a wafer-level process or a chip-level process. For a wafer-level process, substrate removal may be performed prior to a dicing process that forms individual chips having desired dimensions (e.g., about 1×1 mm², about 0.5×0.5 mm²). For a wafer-level process, the sub-mount 39 may be a structure (e.g., metal substrate, semiconductor substrate, ceramic substrate) with similar or larger dimensions as substrate 2, so as to enable a wafer bonding process. Alternatively, for a chip-level process, the substrate may be removed after individual chips or groups of individual chips have been diced. In a chip-level process, sub-mount 39 may be a portion of the package within which the chip will be housed. In some embodiments, a protective layer (not shown) may be provided on the sides of wafer and/or chips prior to substrate removal. The protective layer includes any suitable material (e.g., a silicon nitride) that is resistant to etching in the solution utilized to remove substrate 2.

In some embodiments, substrate 2 may be a ZnO substrate and an etching solution may be utilized to etch ZnO while stopping on etch-stop layer 13. Mechanical removal of at least a portion of the substrate backside may be performed prior to etching, for example grinding and/or CMP may be used to remove a substantial portion of the substrate, thereby shorting the etch time required to remove the remaining portion of the substrate. For example, grinding and/or CMP may be used remove a substantial portion of the substrate backside, leaving less than about 100 μm or even less than about 50 μm. In some embodiments, buffer layer 15 may be formed of materials that are also etched at a much faster rate than etch-stop layer 13. For example, buffer layer 15 may be formed of ZnO or ZnO alloys that etch at a much faster rate than etch-stop layer 13. In embodiments where buffer layer 15 has a textured surface formed during deposition, the interface between buffer layer 15 and etch-stop layer 13 may therefore be textured, and that texture may be revealed after the etching process that may selectively stop on etch-stop layer 13.

Etch-stop layer 13 includes one or more ZnO-based layers that etch slower than ZnO. For example, etch-stop layer 13 includes a ZnO-based alloy that may etch slower than the ZnO substrate material, and/or includes a ZnO-based n-doped or p-doped material that may etch slower than the ZnO substrate.

In a specific example, etch-stop layer 13 includes a ZnO alloy including Cd, for example Zn₁₋ₓCdₓO with 0<x<1, and preferably 0.1<x<0.3. An etching solution may be an 8% by weight NaOH solution, for which the selectivity between ZnO and Zn_{0.8}Cd_{0.2}O is about 10:1. Specifically, utilizing this etching solution, ZnO exhibits an etch rate of about 150 nm/minute and Zn_{0.8}Cd_{0.2}O exhibits an etch rate of about 15 nm/minute. Since substrate 2 may have a starting thickness of about 300 μm to about 500 μm or even larger, a backside grinding process may be employed to thin the backside of the substrate after bonding to sub-mount 39. The thinned substrate may have a thickness of about 100 μm, and thus utilizing the above-mentioned etch solution, the time required to completely remove the substrate is about 11 hours. When the thinned substrate has a smaller thickness of about 50 μm, utilizing the above-mentioned etch solution, the time required to completely remove the substrate is about 5 hours.

In another example, etch-stop layer 13 includes a ZnO alloy including Be, for example Zn₁₋ₓBeₓO with 0<x<1, and preferably about 0.1<x<0.5, and more preferably about 0.1<x<0.3. An etching solution may be a 6% by weight H₂SO₄ solution, for which the selectivity between ZnO and Zn_{0.8}Be_{0.2}O is also about 10:1. Specifically, utilizing this etching solution, ZnO exhibits an etch rate of about 170 nm/minute and Zn_{0.8}Be_{0.2}O exhibits an etch rate of about 17 nm/minute. Since substrate 2 may have a starting thickness of about 300 μm to about 500 μm or even larger, a backside grinding process may employed to thin the backside of the substrate after bonding to sub-mount 39. The thinned substrate may have a thickness of about 100 μm, and thus utilizing the above-mentioned etch solution, the time required to completely remove the substrate is about 10 hours. When the thinned substrate has a smaller thickness of about 50 μm, utilizing the above-mentioned etch solution, the time required to completely remove the substrate is about 5 hours.

In another example, etch-stop layer 13 includes a ZnO alloy including Mg, for example Zn₁₋ₓMgₓO with 0<x<1, and preferably about 0.1<x<0.5, and more preferably about 0.1<x<0.3. An etching solution may a diluted H₃PO₄ solution, for which the selectivity between monocrystalline ZnO and monocrystalline Zn_{0.8}Mg_{0.2}O is also about 3:1. More specifically, in this example, the substrate may be a monocrystalline m-plane ZnO substrate. The ZnO substrate may be cleaned and loaded into a MOCVD reactor and heated to a temperature of about 550° C. Upon reaching the growth temperature, a layer of undoped ZnO having a thickness of about 500 nm may be deposited on the ZnO substrate so as to bury any surface impurities. Then an etch-stop layer of Zn_{0.8}Mg_{0.2}O having a thickness of about 50 nm to about 100 nm may be deposited. After the etch-stop layer deposition step, the device layers (e.g., n-layer, active layer, p-layer) may also be deposited via the MOCVD process. After the MOCVD process is completed, subsequent device processing may be performed prior to mounting the top device layer to a sub-mount, as previously discussed. Then, at least a portion of the backside of the ZnO substrate may be mechanically removed, for example via grinding and/or CMP. A selective etch using H₃PO₄ solution may then be used to selectively remove the remaining portion of the ZnO substrate. Stopping on the etch-stop layer may be achieved via chemical selectively, etch timing, a feedback measurement (e.g., refractive index measurement of the surface being etched), or any combination thereof.

As is appreciated by those in the art, etch selectivity and etch rates may depend on material quality, doping (e.g., p-type, n-type), and/or crystal orientation. Other wet etches that may potentially be utilized to remove the substrate include HNO₃, HCl, HNO₃/HCl, H₃PO₄, H₃PO₄/HCl, H₂SO₄, H₂SO₄/HCl, NaOH, NaOH/HCl, or combinations thereof

To provide an etch-stop across the entire surface of the structure, the etch-stop layer may have a thickness of about 0.1 μm to about 3 μm, preferably about 1 μm and more preferably about 0.25 μm. However, a smaller etch-stop layer thickness may be utilized, for example, the etch-stop layer may have a thickness of about 10 nm to about 100 nm, preferably about 50 nm. The optimal thickness of the etch-stop layer will depend on the selectively of the etch chemistry utilized, as can be determined readily by those of skill in the art. In some embodiments, the etch-stop layer thickness is less than the critical thickness for relaxation of the layer, which depends on the lattice mismatch between the etch-stop layer and the underlying deposition substrate.

In some embodiments, etch-stop layer 13 also serves as a transparent conducting layer 12. In other embodiments, etch-stop layer 13 may be selectively removed so as to expose an underlying transparent conducting layer 12. For example, an etch-stop layer 13 formed of Znᵢ₋ₓCdₓO (e.g., 0.1<x<0.3) may be selectively removed using an HCl and/or H₃PO₄ etch solution when the underlying transparent conducting layer 12 is formed of ZnO or any other suitable material (e.g., ZnO-based material) which etches at a much slower rate in these solutions. The etch solutions include HCl in water and/or H₃PO₄ in water with a concentration of about 10⁻³ M to about 5×10³ M. FIG. 2H illustrates the resulting structure that may be formed using such as process.

FIG. 2I illustrates a cross-sectional view of a structure including a textured surface for transparent conducting layer 12, formed after removal of etch-stop layer 13. The texture may be a result of an etch solution that may texture the surface, for example, an etching solution that may texture a ZnO-based material, as previously described. Alternatively, or additionally, texture formed during the deposition process of the layers may lead to the formation of the surface texture of transparent conducting layers 12.

Although the process described above illustrates a substrate removal process involving the selective etching of the substrate 2, alternatively or additionally, other processes may be utilized to remove part of all of the substrate. In other processes, a release layer may be provided between the substrate and the other layers. In some embodiments, the release layer includes a ZnO-based material. The release layer may be used in a lift-off process whereby the substrate and other layers etch at a slower rate the release layer. The release layer may be an alloyed and/or doped layer (e.g., n-type or p-type), and as is known in the art, alloying and/or doping may be utilized to significantly alter the etch rate of a material. As such, a lateral etching process may be used to etch the release layer which not attaching the substrate and other exposed layers, thereby providing for lift-off or a portion or all of substrate 2.

FIG. 2J illustrates a cross-sectional view of a light-emitting device formed after forming an electrode 14 on the surface of the transparent conductive layer 12 of the structure shown in FIG. 2I. Metal layer(s) that may form electrode 14 may be deposited (e.g., evaporated and/or sputtered) on a patterned mask disposed on transparent conductive layer 12 and that exposes a portion of the device surface. A lift-off process may be used to then form the electrode by selectively removing the mask. For example, a selective etch that etches the mask may be used to remove the mask and form electrode 14 covering a desired portion of the transparent conductive layer 12. Electrode 14 may cover an area of about 50 μm² to about 400 μm², with a preferred area being about 100×100 μm². For a wafer-level process, the wafer including multiple chip regions may then be diced so as to form multiple individual chips.

Various modifications to the above processes and device structure are possible, such as modifications to the texture of one or more layers and/or the presence or absence of specifics layers. Another modification may involve the contacting geometry, for example modifications to the contacting geometry when using an electrically semi-insulating or insulating substrate. Some light-emitting devices that may incorporate some such modifications are described below, and any of these devices may possess a thin portion 4 that may be formed via complete or partial removal of the epitaxial growth substrate 2. The processes utilized to form these other devices are similar to the processes described above, as will be recognized by one of ordinary skill in the art.

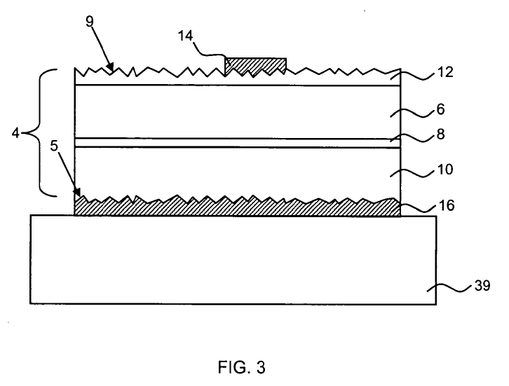

FIG. 3 illustrates a cross-sectional view of a light-emitting device including a textured reflective surface 5. A textured reflective surface may frustrate total internal reflection in the semiconductor structure and facilitate light extraction. Textured reflective surface 5 may be formed as a result of texturing the surface of semiconductor layer 10 prior to the deposition of reflective layers thereon, such as the deposition of reflective metal that may form part of electrode 16. Processes that may be used to texture the surface of semiconductor layer 10 were described in relation to FIG. 2B.

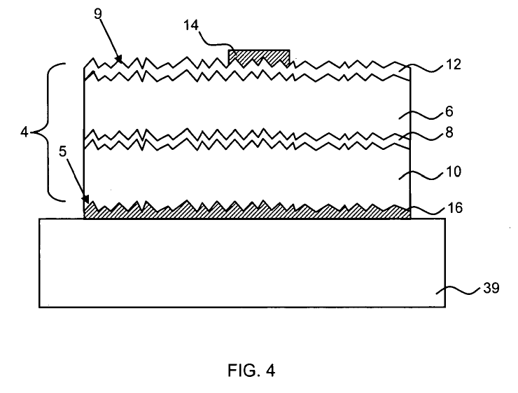

FIG. 4 illustrates a cross-sectional view of a light-emitting device including a plurality of textured layers, such as a textured active layer 8, textured n-type and p-type semiconductor layer 6 and 10, and a textured conducting layer 12. Such as light-emitting device may be formed as a result of depositing a plurality of textured layers as described in relation to the structure of FIG. 2D. Such as structure may then be attached to a sub-mount and a portion or all of the substrate 2 removed, thereby forming the light-emitting device illustrated in FIG. 4.

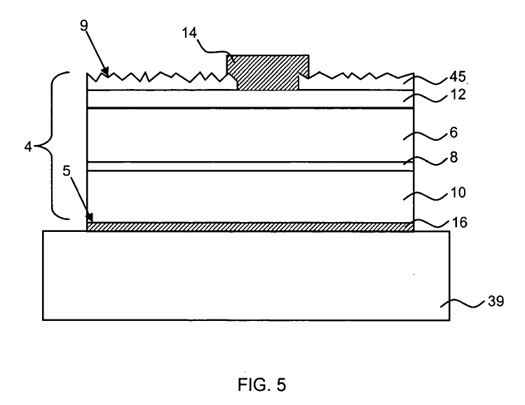

FIG. 5 illustrates a cross-sectional view of another light-emitting device. In this device, a textured layer 45 may be disposed on the transparent conducting layer 12, and a surface of textured layer 45 disposed thereon may serve as a primary light emission surface 9. Texturing of the textured layer 45 may be achieved during deposition of the layers and/or after growth (e.g., via a roughening etch), as previously explained. In one embodiment, textured layer 45 disposed on transparent conducting layer 12 may be etch-stop layer 13 that was described in relation to the fabrication processes that may be used to form the device structure. Textured layer 45 (e.g., etch-stop 13) may be an electrically conductive, insulating, or semi-conducting layer, as electrode 14 may be configured to extend through one or more holes in textured layer 45 so as to make electrical contact with transparent conducting layer 12. To facilitate metal adhesion and electrical contacting, transparent conducting layer 12 may have a smooth surface.

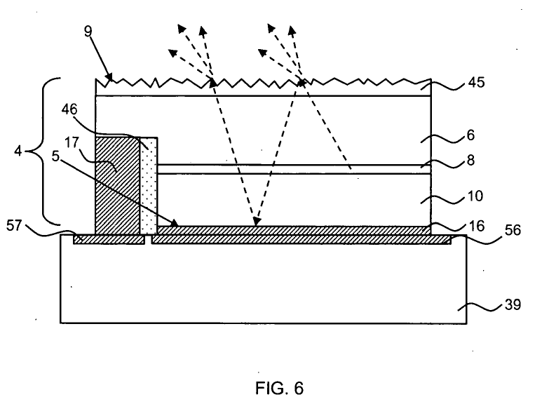

FIG. 6 illustrates a cross-sectional view of a light-emitting device having a lateral electrical contacting geometry and mounted in a flip-chip configuration. Electrodes 17 and 16 may be disposed on the same side of thin portion 4 and may provide electrical contact to semiconductor layers 6 and 10 (e.g., to semiconductor contact layers of semiconductor layers 6 and 10). An electrically insulating material 46 or a void may be provided between electrodes 17 and 16. Electrical contacting of electrodes 17 and 16 to electrically conductive lines (e.g., trace metal lines) 57 and 56, respectively, on sub-mount 39 may be achieved via any suitable attachment process that provides an electrically conductive attachment (e.g., direct bonding, solder attach). In some embodiments, reflective surface 5 may be a textured reflective surface, as previously described. In some embodiments, the surface of electrode 17 that contacts semiconductor layer 6 may also provide a reflective surface, which may optionally be textured.

Textured layer 45 may be an electrically conductive, insulating, or semiconducting layer. In one embodiment, textured layer 45 may be etch-stop layer 13 that was described in relation to the fabrication processes that may be used to form the device structure. A transparent conducting layer may optionally be present adjacent to textured layer 45, but may be omitted, as current spreading may be achieved via laterally through a contact layer of semiconductor layer 6.

The lateral contacting geometry may be formed prior to attachment to the sub-mount and prior to the substrate removal process. The device structure shown in FIG. 6 may be fabricated by performing a masked etch (e.g., dry etching and/or wet etching) of the semiconductor surface so as to expose a contact layer of semiconductor layer 6 in a portion of each chip. Electrode 17 may be formed using metal deposition and a liftoff process, and may utilize similar metals and processes described in relation to the formation of electrode 14 of other embodiments.

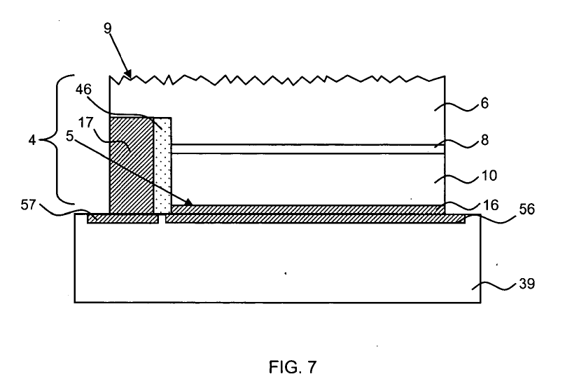

FIG. 7 illustrates a cross-sectional view of a light-emitting device having a lateral electrical contacting geometry and mounted in a flip-chip configuration. The device is similar to the device shown in FIG. 6, except that a surface of semiconductor layer 6 serves as a primary light emission surface 9 that may be textured. As such, textured layer 45 may be omitted. The structure may be formed using processes described in relation to FIG. 2, except that the entire intermediate layer 50 may be removed after substrate removal. Texturing of the surface of semiconductor layer 6 may be achieved during deposition and/or at the end of the substrate removal process, for example, by using a roughening etch.

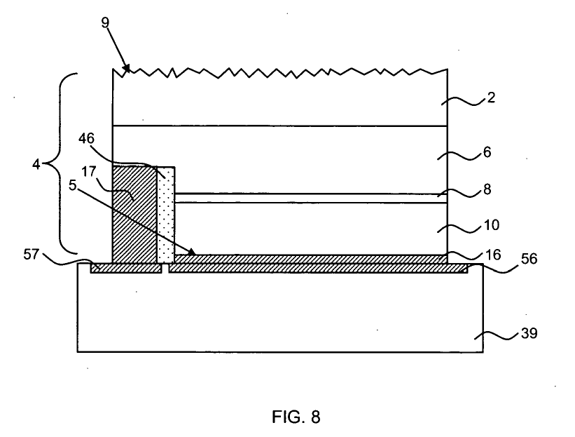

FIG. 8 illustrates a cross-sectional view of a light-emitting device having a lateral electrical contacting geometry and mounted in a flip-chip configuration. The device is similar to the device shown in FIG. 7, except that a portion of substrate 2 may remain in the final device structure. The remaining portion of substrate 2 may be electrically insulating, semi-insulating, or conductive. Such a device structure may still possess a thin portion 4 having a thickness as specified herein, however the structure may be fabricated without using an etch-stop process. Rather a portion of the substrate may be removed (e.g., etched and/or ground) so as to form thin portion 4 that includes a remaining portion of substrate 4. The exposed surface of substrate 4 may be textured using methods described herein, or alternatively, one or more textured layers (not shown) may be formed (e.g., deposited) on the remaining portion of substrate 2.

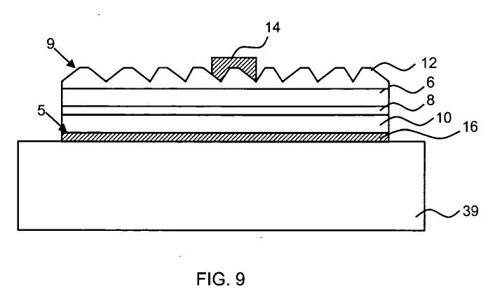

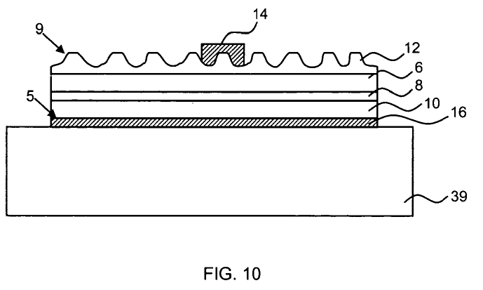

FIGS. 9 and 10 illustrates a cross-sectional view of a light-emitting devices wherein texturing of a primary light emission surface 9 may be achieved via patterning and etching. Additionally, growth texturing and/or a roughening etch may be used to impart additional texturing of the primary light emission surface 9.

Various modifications to the above processes and device structure are possible. Other variations are possible, such as any modification to the contacting geometry, for example modifications to the contacting geometry so as to form same side contacts, such as in a flip-chip configurations. Another variation includes disposing a wavelength converting material over the light emission surface of the device. Waveguide layers can also be added to produce a side-emission device, such as a side-emission laser diode.

As used herein, when a structure (e.g., layer, region) is referred to as being “on”, “over” “overlying” or “supported by” another structure, it can be directly on the structure, or an intervening structure (e.g., layer, region) also may be present. A structure that is “directly on” or “in contact with” another structure means that no intervening structure is present.

The terms “an embodiment”, “embodiment”, “embodiments”, “the embodiment”, “the embodiments”, “an embodiment”, “some embodiments”, and “one embodiment” mean “one or more (but not all) embodiments of the present invention(s)” unless expressly specified otherwise.

The terms “including”, “having,” “comprising” and variations thereof mean “including but not limited to”, unless expressly specified otherwise.

The term “consisting of” and variations thereof mean “including and limited to”, unless expressly specified otherwise.

The enumerated listing of items does not imply that any or all of the items are mutually exclusive. The enumerated listing of items does not imply that any or all of the items are collectively exhaustive of anything, unless expressly specified otherwise. The enumerated listing of items does not imply that the items are ordered in any manner according to the order in which they are enumerated.

The terms “a”, “an” and “the” mean “one or more”, unless expressly specified otherwise.

Headings of sections provided in this patent application and the title of this patent application are for convenience only, and are not to be taken as limiting the disclosure in any way.

The present invention has now been described in connection with a number of specific embodiments thereof. However, numerous modifications which are contemplated as falling within the scope of the present invention should now be apparent to those skilled in the art. Therefore, it is intended that the scope of the present invention be limited only by the scope of the claims appended hereto. In addition, the order of presentation of the claims should not be construed to limit the scope of any particular term in the claims.

What is claimed is:

1. A semiconducting device comprising:
a first semiconductor layer of a first conductivity type;
a second semiconductor layer of a second conductivity type different from the first conductivity type; and
a third semiconductor layer disposed between the first and second layers,
at least one of the first, second and third layers comprising a ZnO-based semiconductor layer,
the dislocation density of the third layer is less than about 10⁶ cm⁻², and
each of the first, second and third layers is free from a growth substrate.

2. The semiconducting device of claim 1, wherein the point defect density of the third layer is not greater than about 10¹⁸ cm⁻³.

3. The semiconducting device of claim 1, wherein each of the first layer, the second layer, and the third layer comprise a ZnO-based semiconductor layer.

4. The semiconducting device of claim 3, wherein the ZnO-based semiconductor layers are mono crystalline layers.

5. The semiconducting device of claim 1, wherein the ZnO-based semiconductor layer is a mono crystalline layer.

6. The semiconducting device of claim 1, further comprising:
a primary light emission surface.

7. The semiconducting device of claim 6, wherein at least a portion of the primary light emission surface is textured.

8. The semiconducting device of claim 1, further comprising:
a reflective layer disposed adjacent a mounting surface of the semiconducting device.

9. The semiconducting device of claim 8, wherein the reflective layer is a broadband reflector with a bandwidth of at least about 400-700 nm.

10. The semiconducting device of claim 1, wherein the third semiconductor layer is oriented substantially parallel to a non-polar plane of the ZnO-based semiconductor.

11. The semiconducting device of claim 1, wherein the third semiconductor layer is oriented substantially parallel to a semi-polar plane of the ZnO-based semiconductor.

12. The semiconducting device of claim 1, wherein the third semiconductor layer is oriented substantially parallel to a polar plane of the ZnO-based semiconductor.

13. The semiconducting device of claim 1, wherein the stacking fault density of the third layer is less than 10⁵ cm⁻¹.

14. The semiconducting device of claim 1, wherein the first semiconductor layer and the second semiconductor layer have a larger energy bandgap than the third semiconductor layer.

15. The light-emitting device of claim 1, wherein the dislocation density is a threading dislocation density of less than 10⁶ cm⁻².

16. The semiconducting device of claim 1, wherein the dislocation density is a threading dislocation density of less than 10⁵ cm⁻².

17. The semiconducting device of claim 1, wherein the dislocation density is a threading dislocation density of less than 10⁴ cm⁻².

18. The semiconducting device of claim 1, wherein the semiconducting device is a light-emitting device and emits light with a peak emission wavelength of less than about 500 nm.

19. A semiconducting device comprising:
a first ZnO-based semiconductor layer of a first conductivity type;
a second ZnO-based semiconductor layer of a second conductivity type different from the first conductivity type; and
a third semiconductor ZnO-based layer,
the third semiconductor ZnO-based disposed between the first and second ZnO-based semiconductor layers,
the dislocation density of the third semiconductor layer is less than about 10⁶ cm⁻², and
each of the first, second and third semiconductor layers is free from a growth substrate.

20. A light-emitting device comprising:
a first semiconductor layer of a first conductivity type;
a second semiconductor layer of a second conductivity type different from the first conductivity type; and
a third semiconductor layer,
the third semiconductor layer disposed between the first and second semiconductor layers,
the dislocation density of the third semiconductor layer is less than about 10⁶ cm⁻²,
each of the first, second and third semiconductor layers is free from a growth substrate, and
wherein a peak emission wavelength of the light-emitting device is less than about 500 nm.

21. A method of fabricating a semiconducting device, comprising:
depositing, on a ZnO-based substrate, a first layer of material, the first layer of material comprising a ZnO-based material;
depositing a second layer of material,
the second layer of material comprising a ZnO-based material with a bandgap different than the bandgap of the first layer of material;
depositing a third layer of material,
the third layer of material comprising a ZnO-based material with a bandgap different than the bandgap of the second layer of material;
the deposition conditions of the first, second and third layers reducing the dislocation density of the second layer below about 10⁶ cm⁻²; and
removing at least a portion of the ZnO-based substrate.

22. The method of claim 21, further comprising the additional step of:
attaching the third layer to a submount.

23. The method of claim 21, further comprising the additional step of:
depositing a fourth layer of material,
the fourth layer of material deposited between the substrate and the first layer of material.

24. The method of claim 23, wherein at least a portion of the ZnO-based substrate is removed using an etchant,
the etchant at least partially selective for the substrate over the fourth layer.

25. The method of claim 23, wherein at least a portion of the ZnO-based substrate is removed using an etchant,
the etchant at least partially selective for the fourth layer over the substrate.

26. The method of claim 21, wherein the bandgaps of the first material and the bandgap of the third material are different.

27. A semiconducting device comprising:
a first layer of a first conductivity type;
a second layer of a second conductivity type different from the first conductivity type; and
a third layer disposed between the first and second layers,
at least one of the first, second and third layers comprising a ZnO-based semiconductor layer,
the dislocation density of the third layer is less than about 10⁶ cm⁻², and
each of the first, second and third layers grown on a substrate thinned to a thickness between about 0 and 50 μm.

28. The product formed according to the method of claim 21.

29. The product formed according to the method of claim 22.

30. The product formed according to the method of claim 24.

31. The product formed according to the method of claim 25.

32. A semiconducting device comprising:
a first layer of a first conductivity type;
a second layer of a second conductivity type different from the first conductivity type;
a third layer disposed between the first and second layers; and
a thinned substrate,
at least one of the first, second and third layers comprising a ZnO-based semiconductor layer,
the dislocation density of the third layer is less than about 10⁶ cm⁻², and
at least one of the first, second and third layers grown on the thinned substrate.

33. The semiconducting device of claim 32, wherein the thinned substrate is thinned from its original thickness.

34. The semiconducting device of claim 32, wherein the thinned substrate is substantially thinned from its original thickness.

35. The semiconducting device of claim 32, wherein the thinned substrate is thinned to a thickness between about 0 and 50 μm.
